(19) United States
(12) Patent Application Publication
(10) Pub. No.: US 2026/0305318 A1
(43) Pub. Date: Oct. 1, 2026

(54) METAL-INSULATOR-METAL (MIM) CAPACITORS AND METHODS OF MAKING THE SAME

(71) Applicant: Advanced Micro Devices, Inc., Santa Clara, CA (US)

(72) Inventor: Vineet Sreekumar, Bangalore (IN)

(73) Assignee: Advanced Micro Devices, Inc., Santa Clara, CA (US)

(21) Appl. No.: 19/093,078

(22) Filed: Mar. 27, 2025

(51) Int. Cl. H01L 23/522; H10D 1/00

(52) U.S. Cl. CPC H10W 20/496; H10D 1/042; H10W 20/42

(57) ABSTRACT

An integrated circuit can include one or more metal layers having one or more interconnects and a metal insulator metal (MIM) capacitor disposed between the metal layers. In some examples, the MIM capacitor can include one or more conductive plates with insulating layers disposed between the conductive plates. In some examples, a plurality of vias can connect the one or more metal layers and the one more conductive plates. In some examples, at least some of the vias do not extend through the entire depth of the MIM capacitor. For example, at least some of the vias can terminate at a conductive plate rather than extend from a first metal layer through one or more conductive plates to a second metal layer. In some examples, the MIM capacitors can realize high capacitance density and low impedance.

### BACKGROUND

Capacitors are commonly used in integrated circuits to perform various functions including stabilizing voltage levels, decoupling alternating current (AC) and direct current (DC) components of signals, and storing energy, among other functions. There are many types of capacitors including metal-insulator-metal (“MIM”) capacitors, metal-oxide-metal (“MOM”) capacitors, and metal-oxide-semiconductor (“MOS”) capacitors. MIM capacitors generally exhibit high capacitance per unit area, stable capacitance values, and low leakage.

### BRIEF DESCRIPTION OF THE DRAWINGS

The accompanying drawings illustrate a number of example implementations and are a part of the specification. Together with the following description, these drawings demonstrate and explain various principles of the present disclosure.

FIG. 1 is a block diagram of an example computer system including an example of a MIM capacitor.

FIG. 2 is a block diagram showing a portion of an integrated circuit including an example MIM capacitor with two conductive plates.

FIG. 3 is a block diagram showing a portion of an integrated circuit including an example MIM capacitor with three conductive plates.

FIG. 4 is a block diagram showing a portion of an integrated circuit including an example MIM capacitor with five conductive plates.

FIG. 5 is a block diagram showing a perspective view of a portion of an integrated circuit including an example MIM capacitor with two conductive plates and two vias that extend from a first metal layer to a second metal layer.

FIG. 6 is a block diagram showing a portion of an integrated circuit including an example MIM capacitor with three conductive plates and two vias that extend from a first metal layer to a second metal layer.

FIG. 7 is a block diagram showing a portion of an integrated circuit including an example MIM capacitor with two conductive plates and several vias, each of which extends from a metal layer to a conductive plate of the MIM capacitor closest to the metal layer.

FIG. 8 is a block diagram showing a portion of an integrated circuit including an example MIM capacitor with three conductive plates and several vias each of which extends from a metal layer to a conductive plate closest to the metal layer.

FIG. 9 is a block diagram showing a portion of an integrated circuit including an example MIM capacitor with three conductive plates and several vias, each of which extends from a metal layer to a conductive plate.

FIG. 10 is a block diagram showing a perspective view of a portion of an integrated circuit including an example MIM capacitor with three conductive plates, two vias that extend from a first metal layer to a second metal layer, and several vias each extending from a metal layer to a conductive plate.

FIG. 11 is a block diagram showing a perspective view of a portion of an integrated circuit including an example MIM capacitor with three conductive plates, two vias that extend from a first metal layer to a second metal layer, and several vias each extending from a metal layer to a conductive plate.

FIG. 12 is a block diagram showing a portion of an integrated circuit including an example MIM capacitor with five conductive plates, two vias that extend from a first metal layer to a second metal layer, and several vias each extending from a metal layer to a conductive plate.

FIG. 13 is a block diagram showing an exemplary view of a metal layer with various interconnects.

FIG. 14 is a block diagram showing a side profile of a portion of an integrated circuit including a metal layer and an insulating layer.

FIG. 15 is a block diagram showing the integrated circuit of FIG. 14, with one or more holes in the insulating layer.

FIG. 16 is a block diagram showing the integrated circuit of FIG. 15, with one or more vias formed in the holes and a first conductive plate formed over the insulating layer.

FIG. 17 is a block diagram showing the integrated circuit of FIG. 16, with a second insulating layer formed over the first conductive plate.

FIG. 18 is a block diagram showing the integrated circuit of FIG. 17, with one or more holes in the second insulating layer.

FIG. 19 is a block diagram showing the integrated circuit of FIG. 18, with one or more vias formed in the holes of the second insulating layer and a second conductive plate formed over the second insulating layer.

FIG. 20 is a block diagram showing the integrated circuit of FIG. 19, with a third insulating layer formed over the second conductive plate.

FIG. 21 is a block diagram showing the integrated circuit of FIG. 20, with one or more holes in the third insulating layer.

FIG. 22 is a block diagram showing the integrated circuit of FIG. 21, with one or more vias formed in the holes of the third insulating layer and a second metal layer formed over the third insulating layer.

FIG. 23 is a block diagram showing the integrated circuit of FIG. 20, with one or more holes in the third insulating layer.

FIG. 24 is a block diagram showing the integrated circuit of FIG. 23, with one or more vias formed in the holes of the third insulating layer and a second metal layer formed over the third insulating layer.

FIG. 25 is a block diagram showing the integrated circuit of FIG. 15, with one or more vias formed in the holes and a first conductive plate formed over the insulating layer.

FIG. 26 is a block diagram showing a MIM capacitor formed on the integrated circuit of FIG. 25.

FIG. 27 is a flowchart of an example method of fabricating a MIM capacitor, according to an example.

FIG. 28 is a block diagram of an electronic design automation (EDA) tool.

FIG. 29 is a block diagram of an example computing device.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure relates to metal-insulator-metal (“MIM”) capacitors and methods for fabricating the same. MIM capacitors generally have high capacitance density and low impedance. Thus, these devices are well-suited for maintaining power integrity and for decoupling signals in integrated circuits, among other uses. In some contexts, the performance of a MIM capacitor is sensitive to the device's impedance (e.g., equivalent series resistance (ESR)). As just one example, when MIM capacitors are used to maintain power integrity (e.g., by reducing or preventing voltage droop) on power lines (or “rails”) in integrated circuits, reducing the capacitor's ESR can (1) improve the capacitor's reliability and efficiency, (2) decrease the amount of heat dissipated by the capacitor, and (3) allow the capacitor to more rapidly supply additional current to the power line's load when the load draws a large current, thereby reducing or preventing voltage droop on the power line. For some applications, the impedances of existing MIM capacitors are too high. Thus, MIM capacitors with lower impedance are needed.

Known methods of decreasing the impedance of a MIM capacitor also reduce the capacitance of the capacitor. For example, increasing the number of through vias connected to the metal layers that provide the terminals of the capacitor and extending through the layers in which the plates of the MIM capacitor are formed can decrease the impedance of the capacitor, at the expense of also decreasing the capacitance (and capacitance density) of the capacitor. This decrease in capacitance (and capacitance density) arises because each through via extends through at least one conductive plate that has a different potential than the through via (e.g., a through via connected to a Vcc node passes through a conductive plate connected to a Vss node). To keep the potentials of these nodes electrically insulated from each other, the conductive plates of the MIM capacitor contain gaps that permit the vias with opposite potential to pass through. The gaps in the conductive plates result in a reduction in MIM density, and thus, a reduction in capacitance of the capacitor. Thus, techniques for fabricating MIM capacitors with high capacitance density and lower impedance are needed.

The present disclosure relates to a process of fabricating MIM capacitors with high capacitance density and lower impedance. In particular, the process can include a step of forming one or more vias between one or more conductive plates and that do not extend through the entire depth of the MIM capacitor. For example, these vias can terminate at a conductive plate, rather than extending from a first metal layer, through one or more conductive plates, to a second metal layer. These vias reduce the impedance of the MIM capacitors. Additionally, in some examples, such vias do not decrease the capacitance density of the capacitor or decrease the capacitance density less than through vias do.

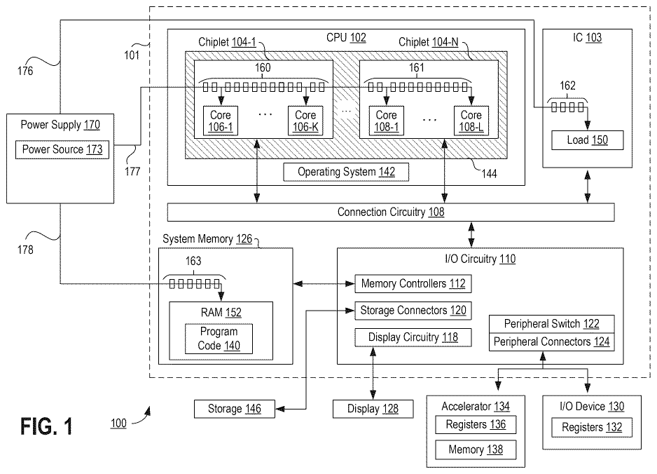

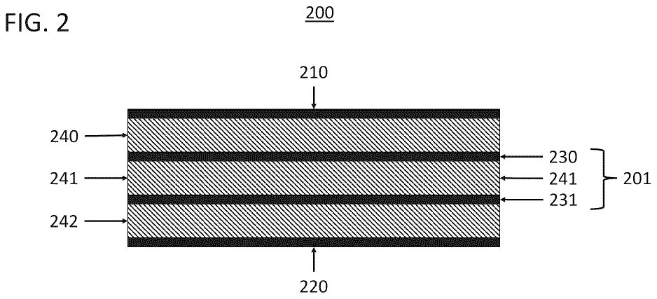

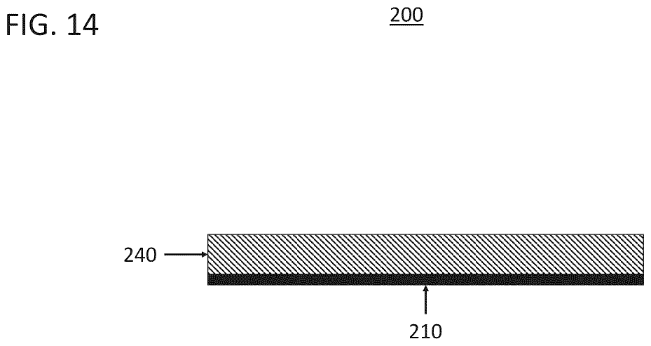

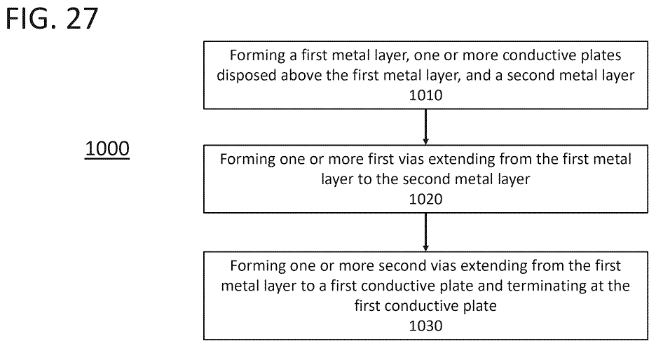

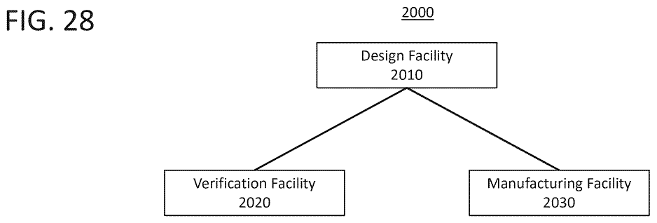

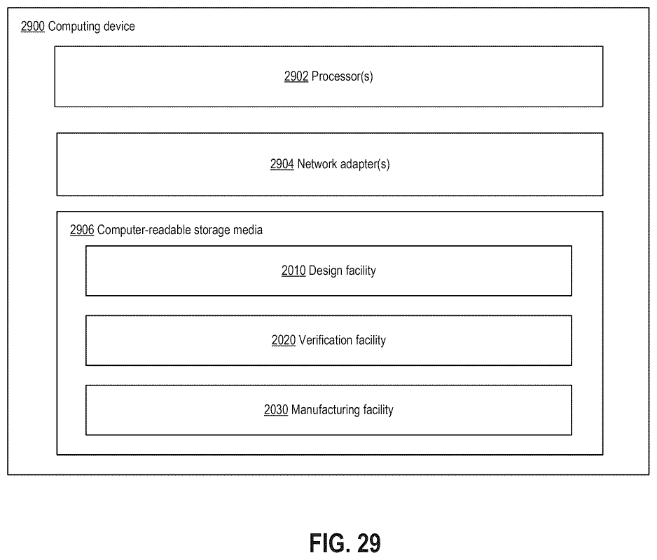

This disclosure provides, with reference to FIG. 1, an example of a computer system including one or more MIM capacitors fabricated in accordance with the techniques described herein. FIGS. 2-13 illustrate examples of MIM capacitors. FIGS. 14-26 illustrate steps in processes of fabricating MIM capacitors. A detailed description of example methods for producing MIM capacitors is provided in connection with FIG. 27. A detailed description of an electronic design automation tool configured to include some examples of MIM capacitors in circuit designs (e.g., integrated circuit layouts) is provided in connection with FIGS. 28-29.

In some aspects, the techniques described herein relate to an integrated circuit including: one or more interconnects formed in a first metal layer; one or more interconnects formed in a second metal layer above the first metal layer; a capacitor disposed between the first and second metal layers, wherein the capacitor includes: a first conductive plate disposed above the first metal layer; a second conductive plate disposed above the first conductive plate; and an insulating layer disposed between the first and second conductive plates; one or more first vias connecting a first interconnect of the one or more interconnects of the second metal layer, the first conductive plate, and a first interconnect of the one or more interconnects of the first metal layer, the one or more first vias being configured to propagate a power supply signal or to couple to a power supply ground node; one or more second vias connecting the first interconnect of the one or more interconnects of the first metal layer to the first conductive plate, the one or more second via terminating below the second conductive plate.

In some aspects, the techniques described herein relate to an integrated circuit, further including one or more third vias connecting a second interconnect of the one or more interconnects of the second metal layer, the second conductive plate, and a second interconnect of the one or more interconnects of the first metal layer, the one or more third vias being configured to propagate the power supply signal or to couple to the power supply ground node.

In some aspects, the techniques described herein relate to an integrated circuit, further including one or more fourth vias connecting the second interconnect of the one or more interconnects of the second metal layer and the second conductive plate, the one or more fourth vias terminating above the first conductive plate.

In some aspects, the techniques described herein relate to an integrated circuit, the one or more first vias being configured to propagate the power supply signal and the one or more third vias being configured to couple to the power supply ground node.

In some aspects, the techniques described herein relate to an integrated circuit, wherein the insulating layer is a first insulating layer, and wherein the capacitor further includes: a third conductive plate formed above the second conductive plate; and a second insulating layer disposed between the second and third conductive plates, the one or more first vias further connecting to the third conductive plate.

In some aspects, the techniques described herein relate to an integrated circuit, further including one or more fifth vias connecting the first interconnect of the one or more interconnects of the second metal layer and the third conductive plate, the one or more fifth vias terminating above the second conductive plate.

In some aspects, the techniques described herein relate to an integrated circuit, wherein the capacitor further includes: a fourth conductive plate formed above the third conductive plate; and a third insulating layer disposed between the third and fourth conductive plates, the one or more third vias further connecting to the fourth conductive plate.

In some aspects, the techniques described herein relate to an integrated circuit, further including one or more sixth vias connecting the second interconnect of the one or more interconnects of the first metal layer to the second conductive plate and/or the fourth conductive plate, the one or more sixth vias terminating below the second metal layer.

In some aspects, the techniques described herein relate to an integrated circuit, further including one or more seventh vias connecting the second interconnect of the one or more interconnects of the second metal layer and the fourth conductive plate, the one or more seventh vias terminating above the third conductive plate.

In some aspects, the techniques described herein relate to an integrated circuit, wherein the capacitor further includes: a fifth conductive plate formed above the fourth conductive plate; and a fourth insulating layer disposed between the fourth and fifth conductive plates, the one or more first vias further connecting to the third conductive plate and the fifth conductive plate.

In some aspects, the techniques described herein relate to an integrated circuit, further including one or more eighth vias connecting the first interconnect of the one or more interconnects of the second metal layer and the fifth conductive plate, the one or more eighth vias terminating above the fourth conductive plate.

In some aspects, the techniques described herein relate to an integrated circuit, wherein at least one of the eighth vias further connects to the third conductive plate and/or the first conductive plate.

In some aspects, the techniques described herein relate to an integrated circuit, further including one or more ninth vias connecting the first interconnect of the one or more interconnects of the first metal layer to the third conductive plate and the first conductive plate, the one or more ninth vias terminating below the fourth conductive plate.

In some aspects, the techniques described herein relate to a method of forming a capacitor in an integrated circuit, the method including: forming one or more interconnects in a first metal layer, a first conductive plate disposed above the first metal layer, an insulating layer disposed above the first conductive plate, a second conductive plate disposed above the insulating layer, and one or more interconnects in a second metal layer disposed above the second conductive plate; forming one or more first vias extending at least from a first interconnect of the one or more interconnects of the first metal layer to a first interconnect of the one or more interconnects of the second metal layer, and connected at least to the first interconnect of the first metal layer, the first conductive plate, and the first interconnect of the second metal layer, the one or more first vias being configured to propagate a power supply signal or couple to a power supply ground node; and forming one or more second vias connecting the first interconnect of the first metal layer to the first conductive plate, the one or more second vias terminating below the second conductive plate.

In some aspects, the techniques described herein relate to a method, further including forming one or more third vias connecting a second interconnect of the one or more interconnects of the second metal layer, the second conductive plate, and a second interconnect of the one or more interconnects of the first metal layer, the one or more third vias being configured to propagate the power supply signal or to couple to the power supply ground node.

In some aspects, the techniques described herein relate to a method, further including forming one or more fourth vias connecting the second interconnect of the one or more interconnects of the second metal layer and the second conductive plate, the one or more fourth vias terminating above the first conductive plate.

In some aspects, the techniques described herein relate to a method, the one or more first vias being configured to propagate the power supply signal and the one or more third vias being configured to couple to the power supply ground node.

In some aspects, the techniques described herein relate to a method, wherein the insulating layer is a first insulating layer, wherein the method further includes forming a second insulating layer above the second conductive plate and a third conductive plate above the second insulating layer and below the second metal layer, and wherein the one or more first vias further connect to the third conductive plate.

In some aspects, the techniques described herein relate to a method, further including one or more fifth vias connecting the first interconnect of the one or more interconnects of the second metal layer and the third conductive plate, the one or more fifth vias terminating above the second conductive plate.

In some aspects, the techniques described herein relate to a method, wherein the method further includes forming a third insulating layer above the third conductive plate and a fourth conductive plate above the third insulating layer and below the second metal layer, and wherein the one or more third vias further connect to the fourth conductive plate.

In some aspects, the techniques described herein relate to a method, further including one or more sixth vias connecting the second interconnect of the one or more interconnects of the first metal layer to the second conductive plate and/or the fourth conductive plate, the one or more sixth vias terminating below the second metal layer.

In some aspects, the techniques described herein relate to a method, further including one or more seventh vias connecting the second interconnect of the one or more interconnects of the second metal layer and the fourth conductive plate, the one or more seventh vias terminating above the third conductive plate.

In some aspects, the techniques described herein relate to a system including: a power supply configured to provide a power supply signal; and an integrated circuit including a load, a power supply line configured to provide the power supply signal to the load, one or more interconnects formed in a first metal layer, one or more interconnects formed in a second metal layer above the first metal layer, and a capacitor disposed between the first and second metal layers; wherein the capacitor is coupled to the power supply line, wherein the capacitor includes a first conductive plate disposed above the first metal layer, a second conductive plate disposed above the first conductive plate, and an insulating layer disposed between the first and second conductive plates, and wherein the integrated circuit further includes one or more first vias connecting a first interconnect of the one or more interconnects of the second metal layer, the first conductive plate, and a first interconnect of the one or more interconnects of the first metal layer, the one or more first vias being configured to propagate the power supply signal, and one or more second vias connecting the first interconnect of the one or more interconnects of the first metal layer to the first conductive plate, the one or more second via terminating below the second conductive plate.

In some aspects, the techniques described herein relate to a system, wherein the load includes a processing core or an array of memory cells.

In some aspects, the techniques described herein relate to a computer-implemented electronic design automation method including: synthesizing, by a computer, an integrated circuit layout from a description of a circuit, the circuit including a capacitor, wherein a portion of the integrated circuit layout includes one or more interconnects formed in a first metal layer, one or more interconnects formed in a second metal layer above the first metal layer, and the capacitor, wherein the capacitor is disposed between the first metal layer and the second metal layer, and wherein the capacitor includes: a first conductive plate disposed above the first metal layer, a second conductive plate disposed above the first conductive plate, and an insulating layer disposed between the first and second conductive plates, and wherein the portion of the integrate circuit layout further includes: one or more first vias connecting a first interconnect of the one or more interconnects of the second metal layer, the first conductive plate, and a first interconnect of the one or more interconnects of the first metal layer, the one or more first vias being configured to propagate a power supply signal or to couple to a power supply ground node, and one or more second vias connecting the first interconnect of the one or more interconnects of the first metal layer to the first conductive plate, the one or more second via terminating below the second conductive plate.

In some aspects, the techniques described herein relate to a method, wherein the description of the circuit includes a logical description of the circuit.

In some aspects, the techniques described herein relate to a method, wherein the description of the circuit includes a schematic and/or a netlist.

In some aspects, the techniques described herein relate to a method, further including simulating, by a computer, operation of the portion of the integrated circuit layout corresponding to the capacitor.

In some aspects, the techniques described herein relate to a method claim 28, further including generating, by a computer, a plurality of mask patterns for fabricating the integrated circuit including the capacitor.

FIG. 1 illustrates one exemplary implementation of a computer system 100 configured to implement the techniques described herein, although others are possible. It should be appreciated that FIG. 1 is intended neither to be a depiction of necessary components for a computer system 100 to operate in accordance with the principles described herein, nor a comprehensive depiction.

Computer system 100 can be, for example, a desktop computer, a video game console, a server, a wireless access point or other networking element, a mobile computing device (e.g., laptop computers, tablets, smartphones, smartwatches, implantable health monitoring devices, wearable computers, personal digital assistants, etc.), or any other suitable computing system. Computer system 100 can comprise at least one central processing unit (CPU) 102, one or more integrated circuits 103 (e.g., processing devices, including but not limited to graphics processing unit (GPU), accelerated processing unit (APU), vision processing unit (VPU), tensor processing unit (TPU), physics processing unit (PPU), digital signal processing (DSP) circuit, field programmable gate array (FPGA), application-specific integrated circuit (ASIC), etc.), connection circuitry 108, I/O circuitry 110, system memory 126, at least one I/O device 130, at least one accelerator 134, storage 146 (e.g., computer-readable storage media), and/or at least one display 128. In some examples, the CPU 102, integrated circuit(s) 103, connection circuitry 108, and I/O circuitry 110, are coupled to (e.g., mounted on) a printed circuit board (e.g., motherboard) 101. An integrated circuit 103 can include a load 150. Additionally or alternatively, the system memory 126 can include a random access memory (RAM) 152. The RAM 152 can store program code 140.

CPU 102 enables processing of data and execution of instructions. The data and instructions can be stored on system memory 126, storage 146, RAM 152, and/or internal memory (not shown) of the CPU 102. In some examples, the CPU 102 includes one or more processor chiplets 104-1 . . . 104-N, which can be disposed on or over a package substrate 144. In some examples, the processor chiplets 104 can communicate with each other via interconnects routed through or on the package substrate 144 (e.g., through an interposer layer disposed between the package substrate 144 and the processor chiplets 104). In some examples, each processor chiplet 104 includes one or more cores (106, 108). Different processor chiplets 104 can have the same or different numbers of cores (106, 108). In the example of FIG. 1, processor chiplet 104-1 has K cores 106-1, 106-2, . . . 106-K, and processor chiplet 104-N has L cores (108-1, 108-2, . . . 108-L). The cores within an individual processor chiplet (e.g., cores 106-1, 106-2, . . . 106-K) can be homogeneous or heterogeneous. Likewise, the cores on different processor chiplets (e.g., cores 106-1 and 108-1) can be homogeneous or heterogeneous.

In the example of FIG. 1, the CPU 102 is configured to execute instructions of an operating system 142 and/or instructions (e.g., program code 140) of one or more applications. In some examples, the functionality of the program code can be implemented by one or more integrated circuits 103, one or more CPUs 102, one or more processor chiplets of a CPU 102, and/or one or more cores of a processor chiplet.

The data and instructions stored on any of the computer-readable storage media (e.g., system memory 126, storage 146, accelerator memory 138, internal or external caches of the CPU 102, etc.) can comprise computer-executable instructions (e.g., program code 140) implementing any suitable functionality.

In some examples, connection circuitry 108 communicatively couples CPUs 102 with each other, with integrated circuit(s) 103, and/or with external caches (e.g., level-2 (L2) cache, level-3 (L3) cache, etc.). Additionally or alternatively, the connection circuitry 108 can communicatively couple the CPUs 102 with I/O circuitry 110, which communicatively couples system memory, storage devices, and peripheral devices to each other and (via the connection circuitry 108) to the CPUs 102. The connection circuitry can couple the CPUs 102, external caches, and I/O circuitry 110 using any suitable network topology (e.g., a front-side bus, a back-side bus, etc.), and the coupled components can send and receive messages via the connection circuitry using any suitable communication protocol. In some examples, portions of the connection circuitry 108 can be integrated into the CPU(s) 102 and/or integrated circuit(s) 103.

In some examples, I/O circuitry 110 includes one or more memory controllers 112, one or more storage connectors 120, display circuitry 118, one or more peripheral connectors 124, and a peripheral switch 122. The memory controller(s) 112 can be configured to control the flow of data to and from the system memory 126. The storage connector(s) 120 can be configured to control the flow of data to and from the storage 146. The display circuitry 118 can be configured to send visual data (e.g., user interface data, image data, video data, etc.) to the display 128, which can be configured to display the visual data. In some examples, the display circuitry 118 can also be configured to receive data representing user input from the display 128 (e.g., in cases where the display 128 includes a touchscreen). In some examples, portions of the I/O circuitry 110 can be integrated into a motherboard and/or motherboard chipset (e.g., I/O circuitry 110) of the computer system 100.

Each of the peripheral connectors 124 can be configured to physically connect and communicatively couple the I/O circuitry 110 to a peripheral device. Any suitable type of peripheral device can be connected to a peripheral connector 124 including, without limitation, an I/O device 130 (e.g., an input device, output device, or input/output device), an accelerator 134, etc. Some non-limiting examples of an input device can include a mouse, keyboard, scanner, video game controller, microphone, webcam, etc. Some non-limiting examples of an output device can include a display, printer, speakers, headphones, earbuds, etc. Some non-limiting examples of an input/output device can include a storage device (e.g., disk drive, solid-state drive, universal serial bus (USB) flash drive, memory card, tape drive, etc.), a networking device (e.g., modem, router, gateway, network adapter, access point, etc.), etc. A networking adapter can be any suitable hardware and/or software to enable the computer system 100 to communicate via wires and/or wirelessly with any other suitable computing system over any suitable computing network. The computing network can include wireless access points, switches, routers, gateways, and/or other networking equipment as well as any suitable wired and/or wireless communication medium or media for exchanging data between two or more computers, including the Internet. Optionally, an I/O device can include one or more registers 132. In some examples, the I/O circuitry 110 can control the operation of an I/O device 130 by writing suitable data to one or more of the I/O device's registers, and/or can monitor the status of an I/O device 130 by reading the contents of one or more of the I/O device's registers.

Some non-limiting examples of an accelerator 134 can include a graphics processing unit (GPU), accelerated processing unit (APU), vision processing unit (VPU), tensor processing unit (TPU), physics processing unit (PPU), digital signal processing (DSP) circuit, field programmable gate array (FPGA), application-specific integrated circuit (ASIC), etc. In some examples, an accelerator 134 includes one or more registers 136 and memory 138. In some examples, the I/O circuitry 110 can control the operation of an accelerator 134 by writing suitable data to one or more of the accelerator's registers, and/or can monitor the status of an accelerator 134 by reading the contents of one or more of the accelerator's registers.

The peripheral switch 122 can be configured to switch packets sent to or from the peripheral devices. Any suitable type of peripheral connector(s) 124 and peripheral switch 122 can be used including, without limitation, universal serial bus (e.g., USB-A, USB-B, USB-C, USB-3.0, etc.), Ethernet, DisplayPort, high-definition multimedia interface (HDMI), peripheral component interconnect (PCI), peripheral component interconnect eXtended (PCI-X), peripheral component interconnect express (PCIe), accelerated graphics port (AGP), etc.

In some examples, the computer system 100 includes or is connected to a power supply 170 that provides power supply signals derived from a power source 173. The power supply 170 can be coupled to various components of the computer system 100 via one or more power lines (e.g., power lines 176-178). Each power line can include one or more portions. For example, portions of a power supply line can include a cable coupling the power supply to the printed circuit board 101, a trace routed across and/or through the printed circuit board 101 to a component of the computer system (e.g., system memory 126, integrated circuit 103, CPU 102, etc.), and one or more power supply lines (e.g., rails) routed across and/or through the component of the computer system and coupled to a load (e.g., RAM 152, load 150, a core, etc.). As illustrated in FIG. 1, the power lines 176-178 can couple the power supply 170 to the RAM 152 of the system memory 126, to the load 150 of the integrated circuit 103, and/or to the cores (106-1-106-K and 108-1-108-L) of the processor chiplets (104-1, 104-N). Each of the power lines 176-178 can include or be coupled to one or more capacitors 160-163. For example, the portions of the power lines routed across and/or through integrated circuit components of the computer system 100 can include or be coupled to one or more capacitors 160-163. The capacitors 160-163 can include one or more MIM capacitors according to the present disclosure.

As described above computer system 100 can have one or more components and peripherals, including input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computing device can receive input information through speech recognition or in other audible format.

FIGS. 2-14 illustrate example portions of integrated circuits including MIM capacitors. A MIM capacitor can include at least two conductive plates. In some examples, a MIM capacitor includes at least one via that terminates at a metal layer of the integrated circuit and at the conductive plate of the MIM capacitor nearest to that metal layer. In some examples, a MIM capacitor includes multiple vias that terminate at a metal layer of the integrated circuit and at the conductive plate of the MIM capacitor nearest to that metal layer. In some examples, these one or more vias terminate at a bottom conductive plate of the MIM capacitor.

FIG. 2 illustrates a portion of an integrated circuit 200 including one exemplary configuration of a MIM capacitor 201. The integrated circuit can include a first metal layer 210 and a second metal layer 220 with the MIM capacitor 201 disposed between. As explained in greater detail below, each metal layer (sometimes referred to as a redistribution layer or interconnect layer) can include one or more interconnects. In some examples, the metal layers can be formed of any suitable conductive material (e.g., aluminum, copper, gold). The MIM capacitor 201 can include a first conductive plate 230, a second conductive plate 231, and a layer 241 of insulating material (e.g., an insulating layer) disposed therebetween. In some examples, the conductive plates (e.g., conductive plates 230-231) can be made of a conductive material. Some non-limiting examples of suitable conductive materials for the conductive plates include aluminum, tungsten, tantalum, titanium nitride, copper, and/or silver, among other conductive materials. In some examples, the insulating material can be a dielectric material. The dielectric material can increase the capacitance of the MIM capacitor. Some non-limiting examples of suitable dielectric materials include silicon dioxide (SiO₂), silicon nitride, polystyrene, and/or titanium dioxide (TiO₂), among others. In some examples, space between the conductive plates (or portions thereof) is occupied by air or is empty (e.g., is a vacuum) rather than being occupied by an insulating material. In some examples, the first metal layer 210 and the first conductive plate 230 are separated by a layer 240 of insulating material. Similarly, in some examples, the second metal layer 220 and the second conductive plate 231 are separated by a layer 242 of insulating material. In some examples, the metal layers (e.g., the first metal layer 210 and the second metal layer 220) and the conductive plates are separated, at least in part, by air or by an empty space (e.g., a vacuum).

In some examples, the first conductive plate 230 has a first electrical potential Vcc and the second conductive plate 231 has a second electrical potential Vss, such that a voltage V=Vcc—Vss is applied across the capacitor. For example, the first conductive plate 230 can be coupled to a power supply line having a nominal electrical potential (e.g., Vcc) and the second conductive plate 231 can be connected to a power supply ground node (e.g., Vss). In some examples, the application of the voltage V across the capacitor causes the capacitor to store an electrical charge.

In some examples, the capacitance of the MIM capacitor 201 is proportional to the area of the conductive plates that face each other. For example, in FIG. 2, the capacitance of the MIM capacitor 201 can be proportional (e.g., directly proportional) to the surface area of the first conductive plate 230 facing the second conductive plate 231 and the surface area of the second conductive plate 231 facing the first conductive plate 230. In some examples, the ratio of a MIM capacitor's capacitance to the opposing surface area of its conductive plates can be referred to as the capacitor's “capacitive density” or “MIM density.”

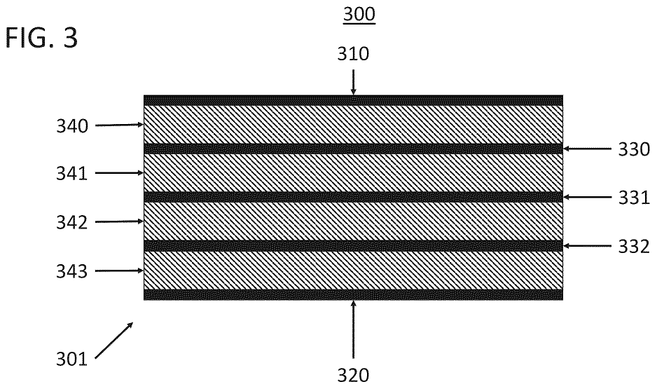

Referring now to FIG. 3, a portion of an integrated circuit 300 can include an example MIM capacitor 301 with three conductive plates (e.g., conductive plates 330-332). In some examples, the portion of the integrated circuit 300 includes a first metal layer 310 and a second metal layer 320. In some examples, layers 340-343 of insulating material (e.g., insulating layers) can be formed between the metal layers (310, 320) and conductive plates (330-332), and between the different conductive plates (330-332). In some examples, the first conductive plate 330 and the third conductive plate 332 can have the same charge. In some examples the second conductive plate 331 can have a different charge than the first conductive plate 330 and the third conductive plate 332. In some examples, the capacitive density of a three-plate MIM capacitor 301 with plates of surface area A1 is greater than (e.g., approximately two times) the capacitive density of a two-plate MIM capacitor 201 with plates of surface area A1, assuming the other parameters of the MIM capacitors (e.g., material types and thicknesses) are the same.

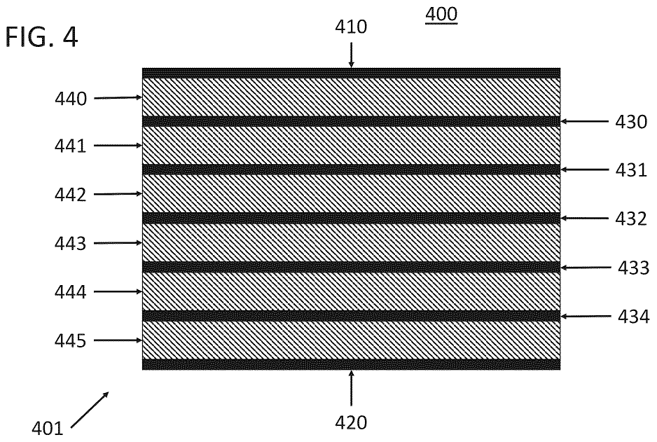

Referring now to FIG. 4, a portion of an integrated circuit 400 can include an example MIM capacitor 401 with five conductive plates (e.g., conductive plates 430-434). In some examples, the portion of an integrated circuit 400 includes a first metal layer 410 and a second metal layer 420. In some examples, insulating layers (e.g., insulating layers 440-445) can be formed between the metal layers (410, 420) and conductive plates (430-434), and between the various conductive plates (430-434). In some examples, the first conductive plate 430, the third conductive plate 432, and the fifth conductive plate 434 can have the same charge. In some examples, the second conductive plate 431 and the fourth conductive plate 433 can have the same charge. In some examples, the charge of the first, third and fifth conductive plates (430, 432, 434) is different than the charge of the second and fourth conductive plates (431, 433). In some examples, the capacitive density of a five-plate MIM capacitor 401 with plates of surface area A1 is greater than (e.g., approximately four times) the capacitive density of a two-plate MIM capacitor 201 with plates of surface area A1, assuming the other parameters of the MIM capacitors (e.g., material types and thicknesses) are the same.

While FIG. 2-4 show example portions of integrated circuits with MIM capacitors that have various numbers of conductive plates, a MIM capacitor can have any suitable number of conductive plates. For example, MIM capacitors can have 4 conductive plates, 6 conductive plates, 7 conductive plates, or more. It is also envisioned that several MIM capacitors can be stacked on top of each other. For example, a second MIM capacitor can be formed on the opposite side of the first metal layer of any of FIGS. 2-4. In some examples, a third metal layer is formed on the opposite side of the second MIM capacitor. This process of forming MIM capacitors and adding metal layers can be repeated.

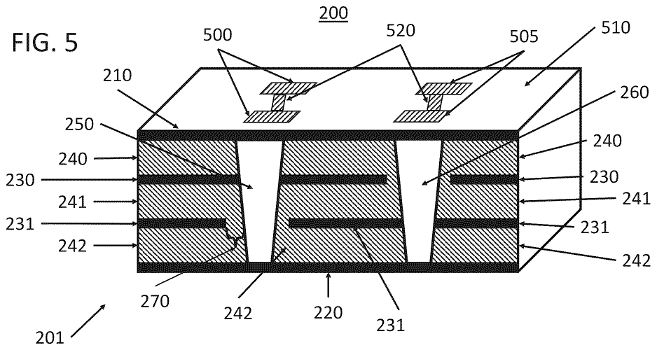

Referring now to FIG. 5, a portion of the integrated circuit 200 including a MIM capacitor 201 can have two conductive plates (230, 231). In some examples, the portion of the integrated circuit 200 including the MIM capacitor 201 can also include one or more through vias (250, 260), one or more metal contacts (500, 505), insulating material 510, and interconnecting material 520. In some examples, the through vias (250, 260) extend from the first metal layer 210 to the second metal layer 220. In some examples, at least a portion of each through via occupies space in the planes otherwise occupied by portions of the one or more of the layers (240-242) of insulating material and/or one or more conductive plates (230-231). In some examples, through via 250 is configured to be coupled to a first voltage node Vcc (e.g., a power supply line having a nominal power supply voltage Vcc), and through via 260 is configured to be coupled to a second voltage node Vss (e.g., a power supply ground node). As shown in FIG. 5, the Vcc via 250 can be connected to the first conductive plate 230 and not connected to the second conductive plate 231. Similarly, the Vss via 260 can be connected to the second conductive plate 231 and not coupled to the first conductive plate 230.

As also shown in FIG. 5, each of the through vias (250, 260) can be connected to the first metal layer 210 and the second metal layer 220. As shown in FIG. 5, metal layers (e.g., the first metal layer 210) can have one or more metal contacts (500, 505). The metal contacts (500, 505) can be selectively coupled to other metal contacts (500, 505) by interconnecting material 520. The metal contacts (500, 505) can be electrically insulated from other metal contacts (500, 505) with an insulative material 510. In some examples, the combination of one or more metal contacts (e.g., metal contacts 505) in a metal layer and interconnecting material 520 in the metal layer coupling the metal contacts can be referred to as an interconnect. In some examples, an interconnect can connect one or more parts of an integrated circuit (e.g., vias, metal contacts, interconnecting material, conductive plates, etc.). The metal layers (e.g., the first metal layer 210 and the second metal layer 220) can have one or more interconnects. In some examples, a metal contact (e.g., a metal contact 500) is coupled to a via (e.g., Vcc via 250). In some examples, a first set of metal contacts 500 are coupled with one or more vias (e.g., Vcc vias) that have a first potential and a second set of metal contacts 505 are coupled with one or more vias (e.g., Vss vias) that have a second potential.

In the example of FIG. 5, two through vias 250 and 260 are shown. However, additional vias can be included in and/or coupled to the MIM capacitor 201. For example, the integrated circuit can include a second Vcc through via coupled to the power supply line and to a second metal contact 500. Similarly, the integrated circuit can include a second Vss through via coupled to the ground node and to a second metal contact 505. Any suitable number of Vcc through vias and/or Vss through vias can be used. In some examples, a first set of vias can be connected to each other through interconnecting material 520 in the first metal layer 210 and/or an interconnect (not shown) in the second metal layer 220. In some examples, the first set of vias can also connect to a first subset of the conductive plates (e.g., the first conductive plate 230) without connecting to a second subset of the conductive plates (e.g., the second conductive plate 231). In some examples, a second set of vias can be connected to each other through interconnecting material 520 in the first metal layer 210 and/or an interconnect (not shown) in the second metal layer 220. In some examples, the second set of vias can connect to the second subset of the conductive plates (e.g., the second conductive plate 231) without connecting to the first subset of conductive plates.

In some examples, there is a gap 270 in the second conductive plate 231 to allow the Vcc via 250 to pass through the second conductive plate 231 without contacting the second conductive plate 231. The gap 270 can be filled with insulating material such as the insulating material of the insulating layers 240-242. The gap 270 and other similar gaps in the MIM capacitor can reduce the MIM density and the capacitance of the MIM capacitor 201. A similar gap can be seen in FIG. 5 relative to the Vss via 260 and the first conductive plate 230.

In some examples, the through vias are spaced apart from each other. In some examples, the through vias are spaced apart at a uniform distance (a “pitch”). Decreasing the pitch of the through vias (e.g., creating more through vias per unit area) can decrease the impedance of the MIM capacitor. However, decreasing the pitch of the vias can also decrease the MIM density because more vias occupy space between the conductive plates and create gaps in the various conductive plates.

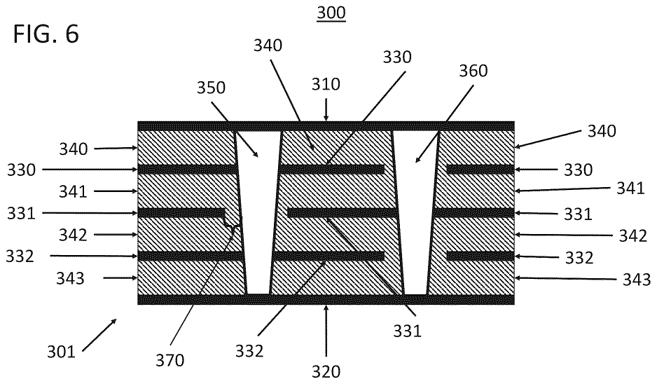

Referring now to FIG. 6, a portion of the integrated circuit 300 including a MIM capacitor 301 can have three conductive plates (330, 331, 332). In some examples, the portion of the integrated circuit 300 including the MIM capacitor 301 can also include one or more through vias (350, 360). In some examples, the through vias (350, 360) extend from the first metal layer 310 to the second metal layer 320. In some examples, at least a portion of each of the through vias occupies space in the planes otherwise occupied by portions of the one or more of the layers (340-343) of insulating material and/or one or more conductive plates (330-332). In some examples, through via 350 is configured to be coupled to a first voltage node Vcc (e.g., a power supply line having a nominal power supply voltage Vcc), and through via 360 is configured to be coupled to a second voltage node Vss (e.g., a power supply ground node). As shown in FIG. 6, the Vcc via 350 can be connected to the first conductive plate 330 and the third conductive plate 332 and not connected to the second conductive plate 331. Similarly, the Vss via 360 can be connected to the second conductive plate 331 and not connected to the first conductive plate 330 or the third conductive plate 332.

The example of FIG. 6 shows two through vias, 350 and 360. However, additional vias can be included in and/or coupled to the MIM capacitor 301. In some examples, a first set of vias can be connected to each other through an interconnect in the first metal layer 310 and/or an interconnect in the second metal layer 320. In some examples, a first set of vias can also connect to a first subset of the conductive plates (e.g., the first conductive plate 330 and the third conductive plate 332) without connecting to a second subset of the conductive plates (e.g., the second conductive plate 331). In some examples, a second set of vias can be connected to each other through an interconnect in the first metal layer 310 and/or an interconnect in the second metal layer 220. In some examples, the second set of vias can connect to the second subset of the conductive plates (e.g., the second conductive plate 231) without connecting to the first subset of conductive plates (e.g., the first conductive plate 330 and the third conductive plate 332). In some examples, there is a gap 370 in the second conductive plate to allow the Vcc via (e.g. Vcc via 350) to pass through the second conductive plate without contacting the second conductive plate 331. The gap 270 and other similar gaps (e.g., gaps in the first conductive plate 330 and third conductive plate 332 allowing the Vss via 360 to pass through without contacting these plates) can be filled with insulating material and can reduce the MIM density and capacitance of the MIM capacitor 301.

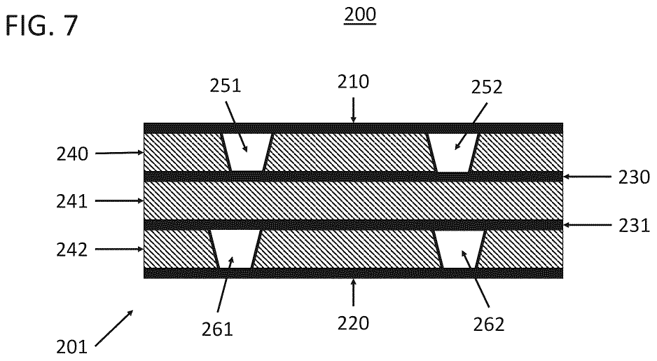

Referring now to FIG. 7, a portion of the integrated circuit 200 including a MIM capacitor 201 can have two conductive plates (230, 231). In some examples, the portion of the integrated circuit 200 including the MIM capacitor 201 can also include one or more vias (251, 252, 261, 262). In some examples, a first set of the vias (e.g., vias 251, 252) connect the first metal layer 210 to the first conductive plate 230 and terminate at the first conductive plate 230 (or above the second conductive plate 231). In some examples, a second set of the vias (e.g., vias 261, 262) connect the second metal layer 220 to the second conductive plate 231 and terminate at the second conductive plate 231 (or below the first conductive plate 230).

In some examples, a via substantially terminates at a conductive plate (or metal layer) if that plate (or metal layer) is the last plate (or metal layer) to which an end of the via connects or through which the end of the via extends. In some examples, a via terminates at a conductive plate and does not extend into the material on the other side of the conductive plate. For example, via 261 of FIG. 7 terminates at the second conductive plate 231 and does not extend into the layer 241 of insulating material on the other side of the conductive plate. In some examples, a via can substantially terminate at a conductive plate and extend into the layer on the other side of the conductive plate. For example, while not shown, via 261 of FIG. 7 can substantially terminate at the second conductive plate 231 and extend beyond the second conductive plate 231 into the layer 241 of insulating material without extending to or through the first conductive plate 230. For example, via 261 can terminate at the first conductive plate and extend through a portion of the next layer 241. In some examples, a stub of a via can extend through a portion of the other side of the conductive plate at which the via substantially terminates. In other words, an end of a via substantially terminates at the conductive plate or metal layer connected nearest to the end of the via, even if the end of the via physically extends beyond (e.g., above or below) that conductive plate or metal layer, so long as that end of the via does not extend through another conductive plate or metal layer.

In some examples, the first set of the vias (251, 252) are configured to be coupled to a first voltage node Vcc (e.g., a power supply line having a nominal power supply voltage Vcc), and the second set of the vias (261, 262) are configured to be coupled to a second voltage node Vss (e.g., a power supply ground node). As shown in FIG. 7, the Vcc vias (251, 252) can be connected to the first conductive plate 230 and not connected to the second conductive plate 231. Similarly, the Vss vias (261, 262) can be connected to the second conductive plate 231 and not connected to the first conductive plate 230.

In the example of FIG. 7, the layer 241 of insulating material between the first conductive plate 230 and the second conductive plate 231 is continuous. The vias (251, 252, 261, 262) do not extend through the insulating layer 241 between the first conductive plate 230 and the second conductive plate 231. In some examples, the conductive plates (e.g., conductive plates 230, 231) are continuous because the vias do not extend through the conductive plates. The vias (251, 252, 261, 262) of FIG. 7 decrease the impedance of the MIM capacitor 201 because they provide additional routes for electricity to move from the conductive plates to a power line or other destinations. Additionally, the vias (251, 252, 261, 262) of FIG. 7 do not substantially decrease the MIM density because they do not cause gaps in the conductive plates and do not extend through the insulating layer 241.

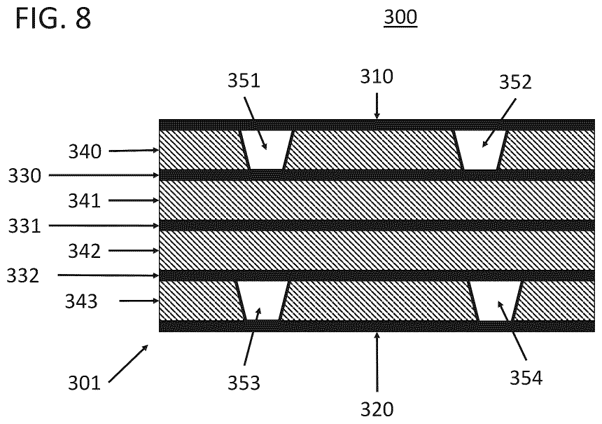

Referring now to FIG. 8, a portion of the integrated circuit 300 including a MIM capacitor 301 can have three conductive plates (330, 331, 332). In some examples, the portion of the integrated circuit 300 can also include one or more vias (351, 352, 353, 354). In some examples, a first set of the vias (351, 352) connect the first metal layer 310 to the first conductive plate 330 and terminate at the first conductive plate 330 (or above the second conductive plate 331). In some examples, a second set of vias (353, 354) connect the second metal layer 320 to the third conductive plate 332 and terminate at the third conductive plate 332 (or below the second conductive plate 331). In some examples, the first set of the vias (351, 352) and the second set of vias (353,354) are configured to be coupled to a first voltage node Vcc (e.g., a power supply line having a nominal power supply voltage Vcc). Like the vias shown in FIG. 7, each via shown in FIG. 8 can substantially terminate at the first conductive plate to which it connects. For example, via 351 is connected to a metal contact of the first metal layer 310 and connects to and terminates at the first conductive plate 330. In the example of FIG. 8, the layers (341, 342) of insulating material disposed between the conductive plates (330-332) are continuous. The vias (351, 352, 353, 354) of FIG. 8, like the vias of FIG. 7, decrease the impedance of the MIM capacitor without substantially decreasing the MIM density.

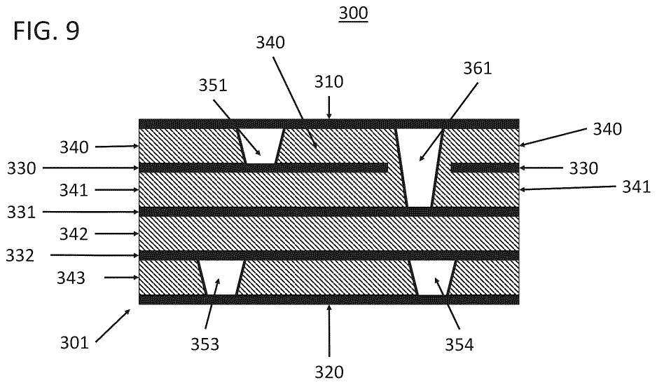

Referring now to FIG. 9, a portion of the integrated circuit 300 including a MIM capacitor 301 can have three conductive plates (330, 331, 332). In some examples, the portion of the integrated circuit 300 including the MIM capacitor 301 can also include one or more vias (351, 353, 354, 361). In some examples, a first set of the vias (e.g., via 351) connect the first metal layer 310 to the first conductive plate 330 and terminate at the first conductive plate 330 (or above the second conductive plate 331). In some examples, a second set of the vias (e.g., vias 353, 354) connect the second metal layer 320 to the third conductive plate 332 and terminate at the third conductive plate 332 (or below the second conductive plate 331). In some examples, a third set of vias (e.g., via 361) connect the first metal layer 310 to the second conductive plate 331 and terminate at the second conductive plate 331 (or above the third conductive plate 332). In some examples, the first set of the vias (e.g., via 351) and the second set of the vias (e.g., vias 353, 354) are configured to be coupled to a first voltage node Vcc (e.g., a power supply line having a nominal power supply voltage Vcc), and the third set of the vias (e.g., via 361) are configured to be coupled to a second voltage node Vss (e.g., a power supply ground node).

As shown in FIG. 9, the third set of the vias (e.g. via 361) creates one or more gaps in the first conductive plate 330. However, the third set of the vias (e.g., via 361) has less of an impact on the MIM density as compared to a through via that extends from the first metal layer 310 to the second metal layer 320 (e.g., the Vss through via 360 of FIG. 6). As seen in FIG. 9, the third set of the vias (e.g., via 361) only interferes with (e.g., reduces the area of) the first conductive plate 330, whereas the Vss through via 360 of FIG. 6 interferes with (e.g., reduces the areas of) the first conductive plate 330 and the third conductive plate 332. Thus, by terminating the third set of the vias (e.g., via 361) at the second conductive plate 331 (or above the third conductive plate 332), the MIM density between the second conductive plate 331 and the third conductive plate 332 is not impacted, while the impedance of the MIM capacitor is decreased.

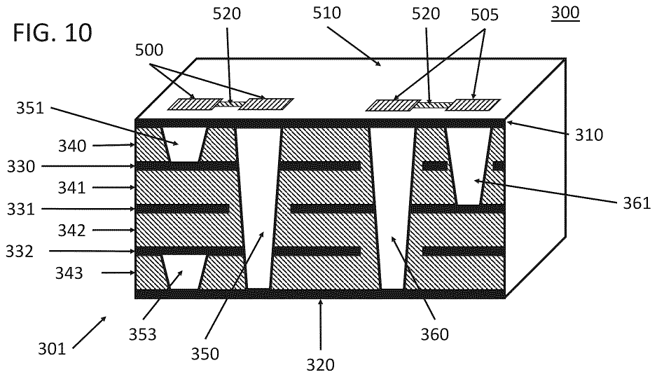

Referring now to FIG. 10, a portion of the integrated circuit 300 including a MIM capacitor 301 can have three conductive plates (330, 331, 332). In some examples, the portion of the integrated circuit 300 including the MIM capacitor 301 can also include one or more vias (350, 351, 353, 360, 361), one or more metal contacts (500, 505), insulating material 510, and interconnecting material 520. In some examples, the vias include one or more through vias (350, 360). In some examples, the through vias (350, 360) extend from the first metal layer 310 to the second metal layer 320. In some examples, at least a portion of each through via (350, 360) occupies space in the planes otherwise occupied by one or more of the layers (340-343) of insulating material and/or one or more conductive plates (330-332). In some examples, a first set of vias (e.g., via 351) connect the first metal layer 310 to the first conductive plate 330 and terminate at the first conductive plate 330 (or above the second conductive plate 331). In some examples, a second set of vias (e.g., via 353) connect the second metal layer 320 to the third conductive plate 332 and terminate at the third conductive plate 332 (or below the second conductive plate 331). In some examples, a third set of vias (e.g., via 361) connects the first metal layer 310 to the second conductive plate 331 and terminates at the second conductive plate 331 (or above the third conductive plate 332). In some examples, a first through via 350, the first set of the vias (e.g., via 351), and the second set of the vias (e.g., via 352) are configured to be coupled to a first voltage node Vcc (e.g., a power supply line having a nominal power supply voltage Vcc), and a second through via 360 and the third set of the vias (e.g., via 361) are configured to be coupled to a second voltage node Vss (e.g., a power supply ground node).

As also shown in FIG. 10, each of the vias (350, 351, 353, 360, 361) can be connected to first metal layer 310 and/or the second metal layer 320. As shown in FIG. 10, metal layers (e.g., the first metal layer 310) can have one or more metal contacts (500, 505) that can be selectively coupled to other metal contacts by interconnecting material 520. As noted above, the metal contacts (e.g., metal contacts 500) and interconnecting material 520 can form one or more interconnects in the metal layers (e.g., metal layer 310). In some examples, a metal contact (e.g., a metal contact 500) is coupled to a via (e.g., through via 350). In some examples, a first set of metal contacts 500 are coupled with one or more vias (e.g., through via 350 and the first set of the vias (e.g., via 351)) that have a first potential, and a second set of metal contacts 505 are coupled with one or more vias (e.g., through via 361 and the third set of the vias (e.g., via 361)) that have a second potential. The various vias can provide different routes for electric current to flow and the various vias have varying impacts on the MIM density. For example, through via 360 connects to the first metal layer 310, the second conductive plate 331, and the second metal layer 320. However, through via 360 also causes the first conductive plate 330 and the third conductive plate 332 to have gaps. Additionally, the third set of vias (e.g., via 361) connects the first metal layer 310 and the second conductive plate 331. The third set of vias does not impact the overall MIM density of the MIM capacitor 301 as much as the through via 360 because the third set of the vias does not impact the third conductive plate 332 or the insulating layer 342 between the second conductive plate 331 and the third conductive plate 332.

In the example of FIG. 10, several vias (e.g., vias 350, 351, 353, 360, 361) are shown. However, additional vias can be included and/or coupled to the MIM capacitor 301. As shown in FIG. 10, a first through via 350 and a first set of the vias (e.g., via 351) can be coupled to metal contacts 500 of the first metal layer 310 and the metal contacts 500 can be connected with interconnecting material 520 (e.g., the first through via 350 and the first set of the vias (e.g., via 351) can be connected to the same interconnect of the first metal layer 310). It is also envisioned that additional vias (i.e., vias in addition to vias 351 and 350) can be connected to the same interconnect of the first metal layer 310. As also shown in FIG. 10, a second through via 360 and a third set of vias (e.g., via 361) can connect to metal contacts 505 that can be connected with interconnecting material 520. It is also envisioned that additional vias (i.e., vias in addition to vias 360 and 361) can be connected to the same interconnect of the first metal layer 310.

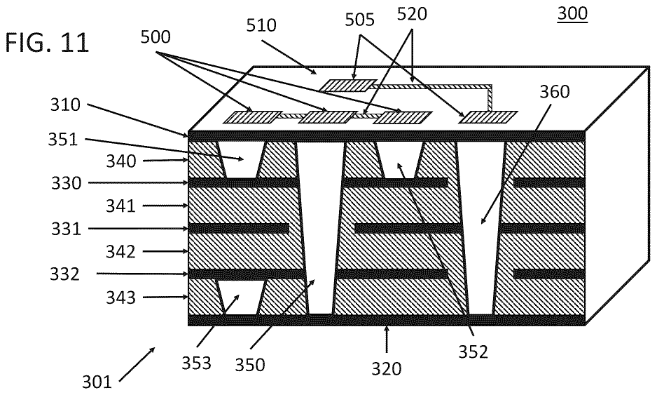

Referring now to FIG. 11, a portion of an integrated circuit 300 including a MIM capacitor 301 can have three conductive plates (330, 331, 332). In some examples, the portion of the integrated circuit 300 including the MIM capacitor 301 can also include one or more vias (350, 351, 352, 353, 360), one or more metal contacts (500, 505), insulating material 510, and interconnecting material 520. In some examples, the vias include one or more through vias (350, 360). In some examples, the through vias (350, 360) extend from the first metal layer 310 to the second metal layer 320. In some examples, at least a portion of each through via (350, 360) occupies space in the planes otherwise occupied by one or more of the layers (340-343) of insulating material and/or one or more conductive plates (330-332). In some examples, a first set of vias (e.g., vias 351, 352) connect the first metal layer 310 to the first conductive plate 330 and terminate at the first conductive plate 330 (or above the second conductive plate 331). In some examples, a second set of vias (e.g., via 353) connect the second metal layer 320 to the third conductive plate 332 and terminate at the third conductive plate 332 (or below the second conductive plate 331). In some examples, a first through via 350, the first set of the vias (e.g., vias 351, 352), and the second set of the vias (e.g., via 353) are configured to be coupled to a first voltage node Vcc (e.g., a power supply line having a nominal power supply voltage Vcc), and a second through via 360 is configured to be coupled to a second voltage node Vss (e.g., a power supply ground node).

In some examples, some of the Vcc vias (e.g., vias 350, 351, 352) are coupled to the same interconnect of the first metal layer. For example, the first through via 350 and the first set of the vias (e.g., vias 351, 352) can each be connected to a metal contact 500, each of the metal contacts 500 being connected with interconnecting material 520. Similarly, the second through via 360 can be connected to a second interconnect of the first metal layer 310. For example, the second through via 360 can be connected to metal contact 505 that is connected to other metal contacts 505 of the first metal layer 310.

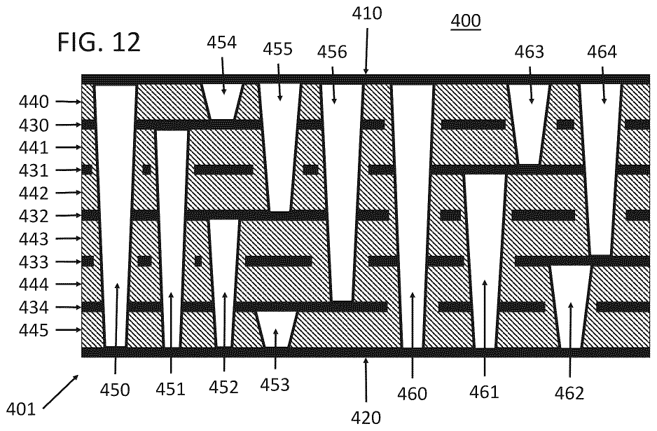

Referring now to FIG. 12, a portion of the integrated circuit 400 including a MIM capacitor 401 can have five conductive plates (430-434). In some examples, the portion of the integrated circuit 400 including the MIM capacitor 401 can also include one or more vias (450-456, 460-464). In some examples, a first set of the vias (e.g., via 450) connects the first metal layer 410, the first conductive plate 430, the third conductive plate 432, the fifth conductive plate 434, and the second metal layer 420. In some examples, a second set of the vias (e.g., via 451) connects the first conductive plate 430, the third conductive plate 432, the fifth conductive plate 434, and the second metal layer 420, and terminates at the first conductive plate 430 (or below the first metal layer 410). In some examples, a third set of the vias (e.g., via 452) connects the third conductive plate 432, the fifth conductive plate 434, and the second metal layer 420, and terminates at the third conductive plate 432 (or below the second conductive plate 431). In some examples, a fourth set of the vias (e.g., via 453) connects the fifth conductive plate 434 and the second metal layer 420, and terminates at the fifth conductive plate 434 (or below the fourth conductive plate 433). In some examples, a fifth set of the vias (e.g., via 454) connects the first metal layer 410 and the first conductive plate 430, and terminates at the first conductive plate 430 (or above the second conductive plate 431). In some examples, a sixth set of the vias (e.g., via 455) connects the first metal layer 410, the first conductive plate 430, and the third conductive plate 432, and terminates at the third conductive plate 432 (or above the fourth conductive plate 433). In some examples, a seventh set of vias (e.g., via 456) connects the first metal layer 410, the first conductive plate 430, the third conductive plate 432, and the fifth conductive plate 434, and terminates at the fifth conductive plate 434 (or above the second metal layer 420).

In some examples, an eighth set of vias (e.g., via 460) connects the first metal layer 410, the second conductive plate 431, the fourth conductive plate 433, and the second metal layer 420. In some examples, a ninth set of vias (e.g., via 461) connects the second conductive plate 431, the fourth conductive plate 433, and the second metal layer 420, and terminates at the second conductive plate 431 (or below the first conductive plate 430). In some examples, a tenth set of vias (e.g., via 462) connects the fourth conductive plate 433 and the second metal layer 420, and terminates at the fourth conductive plate 433 (or below the third conductive plate 432). In some examples, an eleventh set of vias (e.g., via 463) connects the first metal layer 410 and the second conductive plate 431, and terminates at the second conductive plate 431 (or above the third conductive plate 432). In some examples, a twelfth set of vias (e.g., via 464) connects the first metal layer 410, the second conductive plate 431, and the fourth conductive plate 433, and terminates at the fourth conductive plate 433 (or above the fifth conductive plate 434).

In some examples, the first, second, third, fourth, fifth, sixth, and seventh set of vias are configured to be coupled to a first voltage node Vcc (e.g., a power supply line having a nominal power supply voltage Vcc), and the eighth, ninth, tenth, eleventh, and twelfth set of the vias are configured to be coupled to a second voltage node Vss (e.g., a power supply ground node). In some examples, the Vcc vias are connected to one or more of the first, third, and fifth conductive plates (430, 432, 434) and the Vss vias are connected to one or more of the second and fourth conductive plates (431, 433).

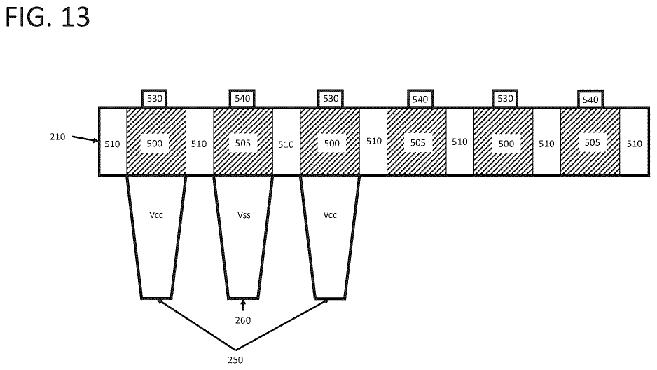

Referring now to FIG. 13, a side view of a metal layer is shown. The metal layer (e.g., a first metal layer 210 of FIG. 2) can contain a plurality of metal contacts (500, 505). In some examples, a first group of metal contacts 500 can have a first potential (e.g., be connected to a power supply line having a nominal power supply voltage Vcc), and a second group of metal contacts 505 can have a second potential (e.g., be connected to a power supply ground node Vss). In some examples, the metal contacts (500, 505) can be connected to vias (250, 260). In some examples, the first group of metal contacts 500 is connected to one or more Vcc vias 250. In some examples, the second group of metal contacts 505 is connected to one or more Vss vias 260. In some examples, the metal contacts (500, 505) are separated by insulating material 510. In some examples, metal contacts (500, 505) in the metal layer 210 can be coupled to bumps (530, 540). In some examples, the bumps (530, 540) can connect the metal layer 210 to one or more other components. For example, the bumps (530, 540) can connect the metal layer to contacts of another integrated circuit.

FIGS. 14-26 illustrate steps in example processes for the manufacturing of a MIM capacitor. The MIM capacitor can include at least two conductive plates. In some examples, the MIM capacitor is disposed between two metal layers. In some examples, the MIM capacitor includes at least one layer of insulating material disposed between the conductive plates and/or between the conductive plates and the metal layers. In some examples, the MIM capacitor includes one or more additional conductive plates and one or more additional layers of insulating material.

FIG. 14 illustrates one exemplary configuration of a portion of an integrated circuit 200 including an insulating layer 240 formed on a first metal layer 210. The first metal layer 210 can be disposed on or over one or more other layers (not shown) of the integrated circuit, which can be formed on or over a wafer (e.g., a silicon wafer). The first metal layer 210 can be formed using any suitable fabrication step(s) (e.g., metal deposition, formation of an etch mask over regions of the metal layer corresponding to contacts and interconnects, etching of the exposed portions of the deposited metal layer, removal of the etch mask, etc.). The insulating layer can be formed on or over the first metal layer 210 using any suitable fabrication step(s) (e.g., material deposition, planarization, etc.).

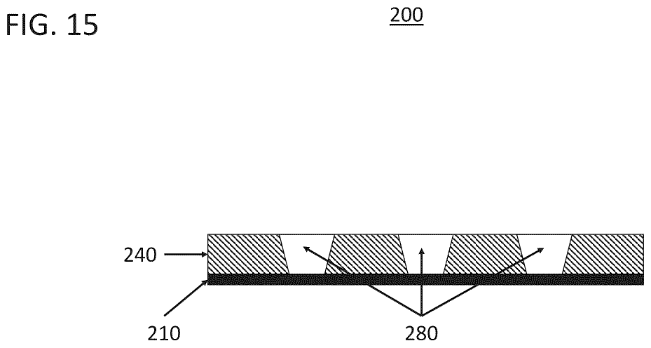

Referring now to FIG. 15, a portion of the layer 240 of insulating material illustrated in FIG. 14 can be removed from the integrated circuit 200 of FIG. 14, thereby forming holes 280 in the insulating material. The holes 280 can be formed using any suitable fabrication step(s) (e.g., formation of a mask and a corresponding mask pattern over regions of the insulation layer 240 to be retained, etching of the exposed portions of the insulation layer 240 to form the holes 280, removal of the mask, planarization, etc.).

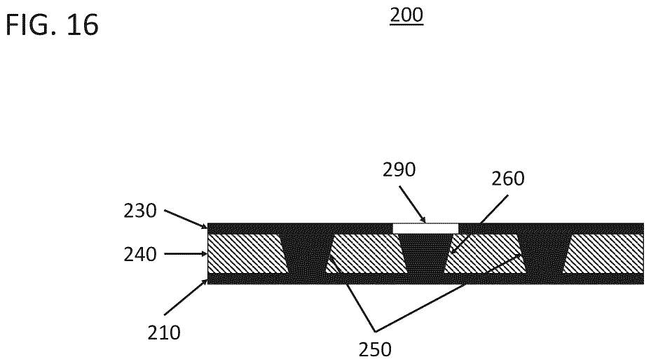

Referring now to FIG. 16, portions of vias (250, 260) can be formed in the holes 280 of the integrated circuit 200 of FIG. 15. The portions of the vias can be formed in the holes 280 using any suitable fabrication step(s). For example, prior to the removal of the mask over the retained regions of the insulating layer 240, a conductive material (e.g., metal) can be deposited in the holes 280.

Still referring to FIG. 16, a first conductive plate 230 can be formed on or over the insulating layer 240. As shown in FIG. 16, one or more gaps 290 (sometimes referred to herein as “holes”) can be formed in the first conductive plate 230. Each gap 290 can prevent the first conductive plate 230 from connecting to (e.g., conductive coupling with) one or more vias (e.g., via 260). In some examples, other vias (e.g., vias 250) can be connected to (e.g., conductive coupled with) the first conductive plate 230. The first conductive plate 230 and the gap(s) 290 can be formed using any suitable fabrication step(s) (e.g., deposition of the plate material, formation of an etch mask over regions of the plate material to be retained, etching of the exposed portions of the deposited plate material, removal of the etch mask, planarization, etc.).

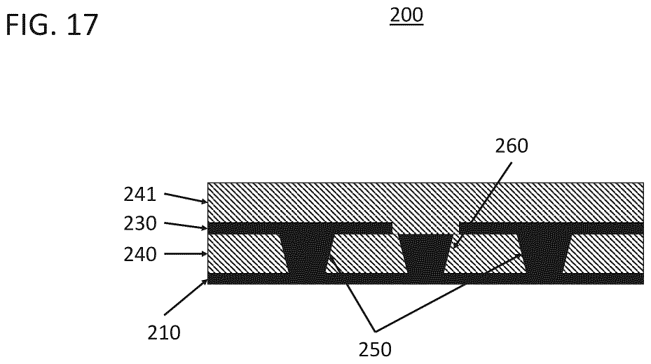

Referring now to FIG. 17, a layer 241 of insulating material can be formed on or over the first conductive plate 230 of the integrated circuit 200 of FIG. 16 using any suitable fabrication step(s). In some examples, the first conductive plate can be planarized before the insulating layer 241 is formed on or over the first conductive plate 230.

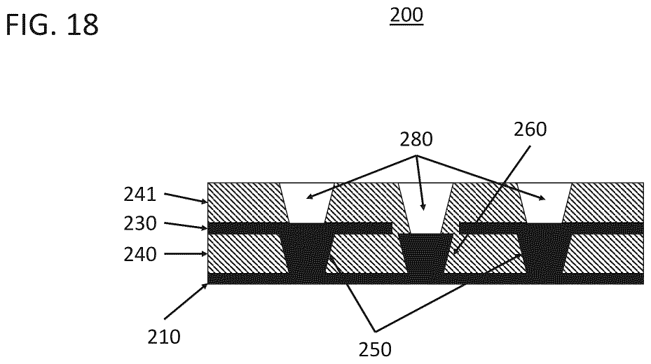

Referring now to FIG. 18, a portion of the layer 241 of insulating material illustrated in FIG. 17 can be removed from the integrated circuit 200 of FIG. 17, thereby forming holes 280 in the insulating material. The holes 280 can be formed using any suitable fabrication step(s). In some examples, the holes 280 in the layer 241 of insulating material can be aligned with the portions of vias (e.g., portions of vias 250, 260).

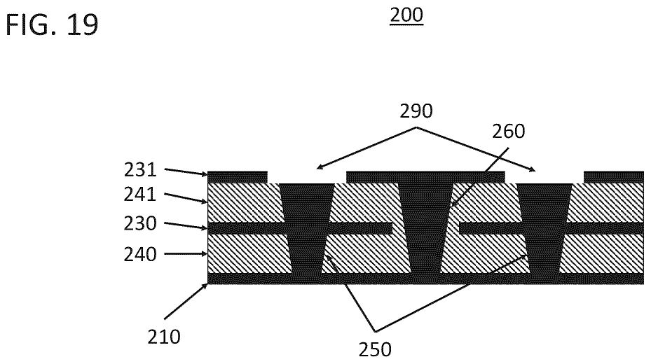

Referring now to FIG. 19, portions of vias (250, 260) can be formed in the holes of the integrated circuit 200 of FIG. 18. The portions of vias can be formed in the holes 280 using any suitable fabrication step(s).

Still referring to FIG. 19, a second conductive plate 231 can be formed on or over the insulating layer 241. As shown in FIG. 19, one or more gaps 290 can be formed in the second conductive plate 231. In some examples, each gap 290 of FIG. 19 is aligned with a portion of a via 260. Each gap 290 can prevent the second conductive plate 231 from connecting to (e.g., conductive coupling with) one or more vias (e.g., vias 250). In some examples, other vias (e.g., via 260) can be connected to (e.g., conductively coupled with) the second conductive plate 231. The second conductive plate 231 and the gap(s) 290 can be formed with any suitable fabrication method.

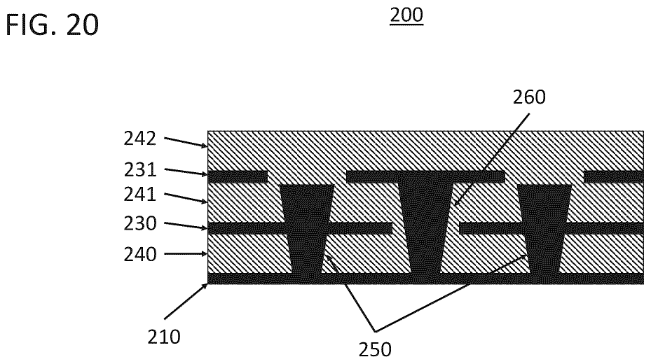

Referring now to FIG. 20, a layer 242 of insulating material can be formed on or over the second conductive plate 231 of the integrated circuit 200 of FIG. 19 sing any suitable fabrication step(s). In some examples, the second conductive plate 231 can be planarized before the insulating layer 241 is formed on or over the second conductive plate 231.

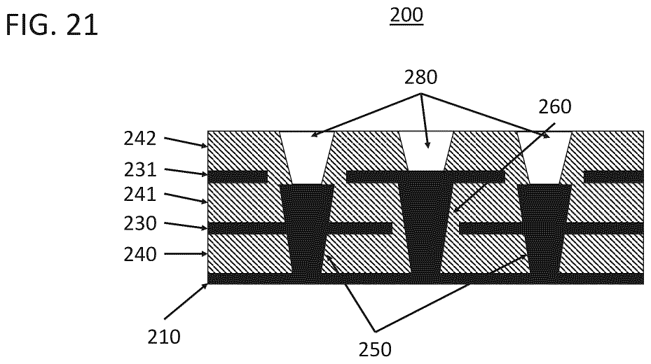

Referring now to FIG. 21, a portion of the layer 242 of insulating material illustrated in FIG. 20 can be removed from the integrated circuit 200 of FIG. 20, thereby forming holes 280 in the insulating material. The holes 280 can be formed using any suitable fabrication step(s).

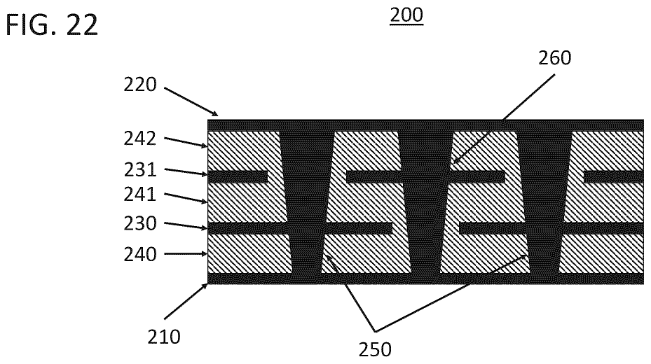

Referring now to FIG. 22, portions of vias (250, 260) can be formed in the holes 280 using any suitable fabrication step(s). In addition, a second metal layer 220 can be formed on or over the insulating layer 242. In some examples, all of the vias (e.g., vias 250, 260) can be connected to (e.g., conductive coupled with) the second metal layer 220. In some examples, the vias (e.g., vias 250, 260) connect to one or more metal contacts (not shown) of the second metal layer 220.

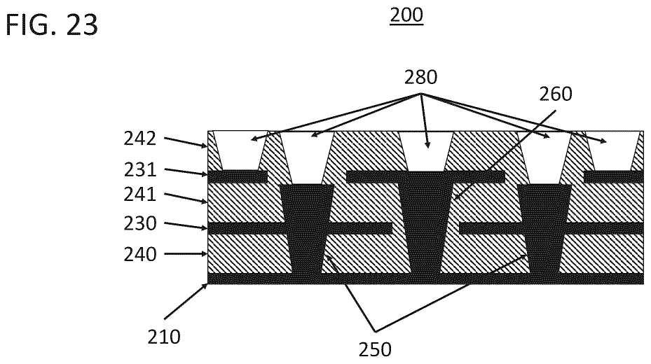

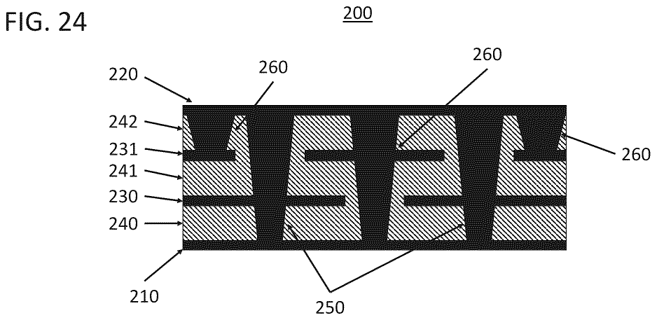

FIG. 23 illustrates the application of an alternate example of a fabrication step to the integrated circuit of FIG. 21. In the example of FIG. 23, additional holes 280 in the layer 242 of insulating material are created. As seen in FIG. 24, vias 260 can be formed in the holes 280 of FIG. 23. FIG. 24 illustrates the resulting portion of an integrated circuit having a MIM capacitor formed from the integrated circuit of FIG. 23.

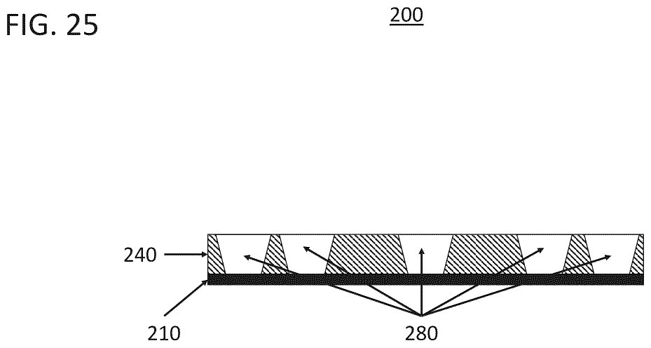

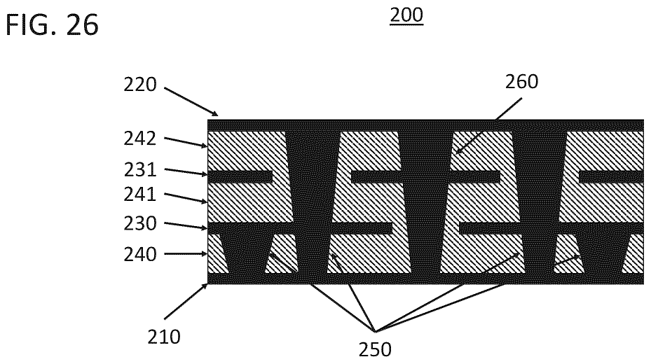

FIG. 25 illustrates the application of an alternate example of a fabrication step to the integrated circuit of FIG. 15. In the example of FIG. 25, additional holes 280 in the layer 240 of insulating material are created. As seen in FIG. 26, vias 250 can be formed in the holes 280 of FIG. 25. FIG. 26 illustrates the resulting MIM capacitor formed from the integrated circuit of FIG. 25.

While various steps are shown above for making an integrated circuit having a MIM capacitor, other processes can be used. For example, holes can be created through one or more insulating layers and/or one or more conductive plates in a single step. In some examples, an integrated circuit having a MIM capacitor with one or more conductive plates is formed, then holes are made in the various layers, and then vias are formed in the holes.

FIG. 27 shows a flowchart of an example method 1000 for producing (e.g., fabricating) an integrated circuit having a MIM capacitor. In some examples, the production method 1000 includes a step 1010 of forming a first metal layer, one or more conductive plates above the first metal layer, and a second metal layer above the conductive plates.

In some examples, the production method 1000 further includes a step 1020 of forming one or more first vias that extend from the first metal layer to the second metal layer. As noted above, the first vias can extend from the first metal layer, through the one or more conductive plates, to the second metal layer. The first vias can selectively connect to one or more conductive plates. Additionally, the formation of the first vias can cause one or more gaps to be formed in one or more of the conductive plates.

In some examples, the production method 1000 further includes a step 1030 of forming one of more second vias extending from the first metal layer to a first conductive plate and terminating at the first conductive plate (or below the second conductive plate). As noted above, various second vias can be formed that connect from a first metal layer to a first conductive plate. In some examples, the second vias can decrease the impedance of the MIM capacitor while also maintaining the capacitance density of the MIM capacitor.

In some examples, the production method 1000 further includes a step of forming one or more third vias extending from the first metal layer to the second metal layer. As noted above, the third vias can extend from the first metal layer, through one or more conductive plates, to the second metal layer. The third vias can selectively connect to one or more conductive plates. In some examples, the third vias connect to different conductive plates than the first vias. Additionally, the formation of the third vias can cause one or more gaps to be formed in one or more of the conductive plates.

In some examples, the production method 1000 further includes a step of forming one or more fourth vias extending from the second metal layer to the second conductive plate and terminating at the second conductive plate (or above the first conductive plate).

In some examples, the one or more first vias and/or the one or more second vias can be configured to propagate the power supply signal (e.g., from a power supply line having a nominal power supply voltage Vcc). In some examples, the one or more third vias and/or fourth vias can be configured to couple to the power supply ground node. Some examples of techniques for carrying out the steps of the MIM capacitor production method 1000 are described above with reference to FIGS. 14-26. Although FIGS. 14-26 illustrate the production of a 2-plate MIM capacitor, one of ordinary skill in the art will appreciate that the illustrating techniques for forming conductive plates, insulating layers, and vias can be repeated one or more times to produce a MIM capacitor having any suitable number of plates.

### Electronic Design Automation (EDA) Tools

In some examples, an electronic design automation (EDA) tool can be configured to facilitate design, simulation, verification, and manufacturing of circuits that include MIM capacitors. In general, EDA tools are used to design, simulate, verify, and/or prepare for manufacturing of electronic systems (e.g., integrated circuits, printed circuit boards, etc.). In some examples, an EDA tool can be a computer-implemented EDA tool.

As shown in FIG. 28, some examples of an EDA tool 2000 can include one or more facilities, for example, a design facility 2010, a verification facility 2020, and/or a manufacturing facility 2030. The design facility 2010 can be operable to perform one or more design steps, including, without limitation, a system design step, a logic design step, a circuit synthesis step, a floor planning step, and/or a physical implementation step. In the system design step, the design facility 2010 can receive (e.g., from a user) a description of the functionality to be implemented by the system, and can perform hardware-software architecture partitioning of the described functionality. Examples of EDA software tools from Synopsys, Inc. that can be used to perform the system design step include Model Architect, Saber, System Studio, and DesignWare® products.

In the logic design step, the design facility 2010 can obtain a high-level logical description of the system (e.g., a description of the system in a hardware design language (HDL), including, but not limited to Verilog or VHDL). In some examples, the design facility 2010 generates the logical description of the system (or portions thereof) based on the functional description of the system. In some examples, the design facility 2010 receives the logical description of the system (or portions thereof) from a user. Examples of EDA software tools from Synopsys, Inc. that can be used to perform the logic design step include VCS, VERA, DesignWare®, Magellan, Formality, ESP and LEDA products.

In the synthesis step, the design facility 2010 can translate the high-level logical description of the system into a circuit schematic, which can be represented by a netlist or any other suitable description of a circuit's components and connections there between. In some examples, this synthesis step can include selection of one or more standard cells to perform logic functions specified in the high-level logical description of the circuit. In some examples, the schematic can be customized for a particular IC technology (e.g., the IC technology that will be used to implement the system). Examples of EDA software tools from Synopsys, Inc. that can be used to perform the synthesis step include Design Compiler®, Physical Compiler, DFT Compiler, Power Compiler, FPGA Compiler, TetraMAX, and DesignWare® products.

In the floor planning step, the design facility 2010 can generate a floor plan for an IC that will implement the system or a portion thereof. Examples of EDA tools from Synopsys, Inc. that can be used to perform the floor planning step include Astro and Custom Designer products.

In the physical implementation step, the design facility 2010 can generate a representation of a physical implementation of the system (e.g., a physical layout of the components of the system on an IC). Generating the representation of the system's physical implementation can include “placing” the circuit's components (determining positions on the IC for the circuit's components) and routing the circuit's connections (determining the positions on the IC of the electrical conductors coupling the circuit's components). In some examples, this physical implementation step can include selection of one or more standard cells to implement circuit components included in the circuit schematic. Examples of EDA tools from Synopsys, Inc. that can be used to perform the physical implementation step include the Astro, IC Compiler, and Custom Designer products.

Returning to FIG. 28, the verification facility 2020 can perform one or more verification steps, including, without limitation, a simulation step, a functional verification step, a schematic verification (e.g., netlist verification) step, a transistor-level verification step, a floor plan verification step, and/or a physical verification step. In the simulation step, the verification facility 2020 can simulate the operation of a representation of the system (e.g., a high-level logical description, circuit schematic, floor plan, or layout of the system).

In the functional verification step, the verification facility 2020 can check the high-level logical description of the system for functional accuracy. For example, the verification facility 2020 can simulate the operation of the high-level logical description of the circuit in response to particular inputs to determine whether the logical description of the circuit produces correct outputs in response to the inputs. Examples of EDA tools from Synopsys, Inc. that can be used at the functional verification step include VCS, VERA, DesignWare®, Magellan, Formality, ESP and LEDA products.

In the schematic verification step, the verification facility 2020 can check the system schematic (e.g., the system netlist) for compliance with applicable timing constraints and for correspondence with the high-level logical description of the circuit. Examples of EDA tools from Synopsys, Inc. that can be used at the verification step include Formality, PrimeTime, and VCS products.

In the transistor-level verification step, the verification facility 2020 can check a transistor-level representation of the system for compliance with applicable timing constraints and for correspondence with the high-level logical description of the circuit. Examples of EDA tools from Synopsys, Inc. that can be used at the transistor-level verification step include AstroRail, PrimeRail, PrimeTime, and Star-RCXT products.

In the floor plan verification step, the verification facility 2020 can check the floor plan of the system for compliance with applicable constraints (e.g., timing, top-level routing, etc.).

In the physical verification step, the verification facility 2020 can check the representation of the physical implementation of the system (e.g., a physical layout of the system components on an IC) for compliance with manufacturing constraints, electrical constraints, lithographic constraints, and/or schematic constraints. The Hercules product from Synopsys, Inc. is an example of an EDA tool that can be used at the physical verification step.

Returning to FIG. 28, the manufacturing facility 2030 can perform one or more steps to prepare for manufacturing the system, including, without limitation, a tape-out step and/or a resolution enhancement step. In the tape-out step, the manufacturing facility 2030 can generate tape-out data to be used (e.g., after lithographic enhancements are applied) for production of masks for lithographic fabrication of ICs that implement the system. Examples of EDA tools from Synopsys, Inc. that can be used at the tape-out step include the IC Compiler and Custom Designer families of tools.

In the resolution enhancement step, the manufacturing facility 2030 can perform geometric manipulations of the system's physical layout to improve manufacturability of the IC. Examples of EDA software products from Synopsys, Inc. that can be used at this resolution enhancement step include Proteus, ProteusAF, and PSMGen tools.

An EDA tool can perform an EDA method including one or more (e.g., all) of the above-described design, verification, and/or manufacturing steps in any suitable order. In some examples, one or more of the design, verification, and/or manufacturing steps can be performed iteratively (e.g., until the tool determines that the system satisfies particular constraints and/or passes particular tests).

In some examples, one or more EDA tools can operate to design, verify, and/or fabricate a circuit that includes a MIM capacitor. For example, an EDA tool can be used to synthesize a schematic of a circuit that includes one or more MIM capacitors (e.g., based on a logical description of the circuit or portions thereof). Alternatively, a user can provide the EDA tool with a schematic of a circuit that includes one or more MIM capacitors. Based on the schematic (or any other suitable representation of the circuit), the EDA tool can generate a representation of a physical implementation of the circuit (e.g., a physical layout of the components of the circuit on an IC).

The physical layout of the circuit can include one or more interconnects formed in a first metal layer, one or more interconnects formed in a second metal layer above the first metal layer, and a MIM capacitor disposed between the first and second metal layers. The MIM capacitor can include a first conductive plate disposed above the first metal layer, a second conductive plate disposed above the first conductive plate, and an insulating layer disposed between the first and second conductive plates. The physical layout of the circuit can further include one or more first vias connecting a first interconnect of the one or more interconnects of the second metal layer, the first conductive plate, and a first interconnect of the one or more interconnects of the first metal layer. The one or more first vias can be configured to propagate a power supply signal or to couple to a power supply ground node. The physical layout of the circuit can further include one or more second vias connecting the first interconnect of the one or more interconnects of the first metal layer to the first conductive plate, the one or more second vias terminating below the second conductive plate.

As another example, an EDA tool can generate lithographic masks suitable for fabricating the physical implementation of the circuit, including the multi-bit transmission gate. In some examples, these lithographic masks can be used with one or more process technologies to fabricate an IC that implements the circuit.

EDA techniques operating according to the principles described herein can be implemented in any suitable manner. While the foregoing disclosure sets forth various implementations using specific block diagrams, flowcharts, and/or examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered as non-limiting examples since many other architectures can be implemented to achieve the same functionality.

Included in the discussion above are examples of steps and acts of EDA processes. These steps and acts can be included in algorithms that carry out these EDA processes. Algorithms derived from these processes (or steps thereof) can be implemented as software integrated with and directing the operation of one or more single-or multi-purpose processors (e.g., central processing units (CPUs), graphics processing units (GPUs), tensor processing units (TPUs), hardware accelerators, etc.), can be implemented as functionally-equivalent circuits such as a Digital Signal Processing (DSP) circuit, Field Programmable Gate Array (FPGA), or an Application-Specific Integrated Circuit (ASIC), or can be implemented in any other suitable manner. It should be appreciated that the EDA step(s) and act(s) described herein are not limited to the syntax or operation of any particular circuit or of any particular programming language or type of programming language. Rather, the description of the EDA tool illustrates the functional information one of ordinary skill in the art can use to fabricate circuits or to implement computer software algorithms to perform the processing of a particular apparatus carrying out the types of techniques described herein.

Accordingly, in some examples, the EDA techniques described herein can be embodied in computer-executable instructions implemented as software, including as application software, system software, firmware, middleware, embedded code, or any other suitable type of software. Such computer-executable instructions can be written using any of a number of suitable programming languages and/or programming or scripting tools, and also can be compiled as executable machine language code or intermediate code that is executed on a framework or virtual machine.

When techniques described herein are embodied as computer-executable instructions, these computer-executable instructions can be implemented in any suitable manner, including as a number of functional facilities, each providing one or more operations to complete execution of algorithms operating according to these techniques. A “functional facility,” however instantiated, is a structural component of a computer system that, when integrated with and executed by one or more computers, causes the one or more computers to perform a specific operational role. A functional facility can be a portion of or an entire software element. For example, a functional facility can be implemented as a function of a process, or as a discrete process, or as any other suitable unit of processing. If techniques described herein are implemented as multiple functional facilities, each functional facility can be implemented in its own way; all need not be implemented the same way. Additionally, these functional facilities can be executed in parallel and/or serially, as appropriate, and can pass information between one another using a shared memory on the computer(s) on which they are executing, using a message passing protocol, or in any other suitable way.

Generally, functional facilities include routines, programs, objects, components, data structures, etc. that perform particular tasks or implement particular abstract data types. Typically, the functionality of the functional facilities can be combined or distributed as desired in the systems in which they operate. In some implementations, one or more functional facilities carrying out techniques herein can together form a complete software package. These functional facilities can, in alternative examples, be adapted to interact with other, unrelated functional facilities and/or processes, to implement a software program application. In other implementations, the functional facilities can be adapted to interact with other functional facilities in such a way as form an operating system, including the Windows® operating system, available from the Microsoft® Corporation of Redmond, Washington. In other words, in some implementations, the functional facilities can be implemented alternatively as a portion of or outside of an operating system.

Some exemplary functional facilities have been described herein for carrying out one or more tasks. It should be appreciated, though, that the functional facilities and division of tasks described is merely illustrative of the type of functional facilities that can implement the exemplary techniques described herein, and that examples are not limited to being implemented in any specific number, division, or type of functional facilities. In some implementations, all functionality can be implemented in a single functional facility. It should also be appreciated that, in some implementations, some of the functional facilities described herein can be implemented together with or separately from others (i.e., as a single unit or separate units), or some of these functional facilities can be omitted.

Computer-executable instructions implementing the techniques described herein (when implemented as one or more functional facilities or in any other manner) can, in some embodiments, be encoded on one or more computer-readable media to provide functionality to the media. Computer-readable media include magnetic media such as a hard disk drive, optical media such as a Compact Disk (CD) or a Digital Versatile Disk (DVD), a persistent or non-persistent solid-state memory (e.g., Flash memory, Magnetic RAM, etc.), or any other suitable storage media. Such a computer-readable medium can be implemented in any suitable manner, including as computer-readable storage media 2906 of computing device 2900 (see FIG. 29) or as a stand-alone, separate storage medium. As used herein, “computer-readable media” (also called “computer-readable storage media”) refers to tangible storage media. Tangible storage media are non-transitory and have at least one physical, structural component. In a “computer-readable medium,” as used herein, at least one physical, structural component has at least one physical property that can be altered in some way during a process of creating the medium with embedded information, a process of recording information thereon, or any other process of encoding the medium with information. For example, a magnetization state of a portion of a physical structure of a computer-readable medium can be altered during a recording process.

Further, some techniques described above comprise acts of storing information (e.g., data and/or instructions) in certain ways for use by these techniques. In some implementations of these techniques-such as implementations where the techniques are implemented as computer-executable instructions-the information can be encoded on a computer-readable storage media. Where specific structures are described herein as advantageous formats in which to store this information, these structures can be used to impart a physical organization of the information when encoded on the storage medium. These advantageous structures can then provide functionality to the storage medium by affecting operations of one or more processors interacting with the information; for example, by increasing the efficiency of computer operations performed by the processor(s).

In some, but not all, implementations in which the techniques can be embodied as computer-executable instructions, these instructions can be executed on one or more suitable computing device(s) operating in any suitable computer system, or one or more computing devices (or one or more processors of one or more computing devices) can be programmed to execute the computer-executable instructions. A computing device or processor can be programmed to execute instructions when the instructions are stored in a manner accessible to the computing device/processor, such as in a local memory (e.g., an on-chip cache or instruction register, a computer-readable storage medium accessible via a bus, a computer-readable storage medium accessible via one or more networks and accessible by the device/processor, etc.). Functional facilities that comprise these computer-executable instructions can be integrated with and direct the operation of a single multi-purpose programmable digital computer apparatus, a coordinated system of two or more multi-purpose computer apparatuses sharing processing power and jointly carrying out the techniques described herein, a single computer apparatus or coordinated system of computer apparatuses (co-located or geographically distributed) dedicated to executing the techniques described herein, one or more Field-Programmable Gate Arrays (FPGAs) for carrying out the techniques described herein, or any other suitable system.

FIG. 29 illustrates one exemplary implementation of a computing device in the form of a computing device 2900 that can be used in a system implementing an EDA tool, although others are possible. It should be appreciated that FIG. 29 is intended neither to be a depiction of necessary components for a computing device to operate in accordance with the principles described herein, nor a comprehensive depiction.

Computing device 2900 can comprise at least one processor 2902, a network adapter 2904, and computer-readable storage media 2906. Computing device 2900 can be, for example, a desktop or laptop personal computer, a personal digital assistant (PDA), a smart mobile phone, a server, a wireless access point or other networking element, or any other suitable computing device. Network adapter 2904 can be any suitable hardware and/or software to enable the computing device 2900 to communicate wired and/or wirelessly with any other suitable computing device over any suitable computing network. The computing network can include wireless access points, switches, routers, gateways, and/or other networking equipment as well as any suitable wired and/or wireless communication medium or media for exchanging data between two or more computers, including the Internet. Computer-readable storage media 2906 can be adapted to store data to be processed and/or instructions to be executed by one or more processors 2902. Processor 2902 enables processing of data and execution of instructions. The data and instructions can be stored on the computer-readable storage media 2906.

The data and instructions stored on computer-readable storage media 2906 can comprise computer-executable instructions implementing techniques of the EDA tool which operate according to the principles described herein. In the example of FIG. 29, computer-readable storage media 2906 stores computer-executable instructions implementing various facilities and storing various information as described above, including design facility 2010, verification facility 2020, and manufacturing facility 2030 of the EDA tool 2000.

While not illustrated in FIG. 29, a computing device can additionally have one or more components and peripherals, including input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computing device can receive input information through speech recognition or in other audible format.

Examples have been described where the techniques are implemented in circuitry and/or computer-executable instructions. It should be appreciated that some examples can be in the form of a method, of which at least one example has been provided. The acts performed as part of the method can be ordered in any suitable way. Accordingly, examples can be constructed in which acts are performed in an order different than illustrated, which can include performing some acts simultaneously, even though shown as sequential acts in illustrative examples.

Techniques operating according to the principles described herein can be implemented in any suitable manner. While the foregoing disclosure sets forth various implementations using specific block diagrams, flowcharts, and examples, each block diagram component, flowchart step, operation, and/or component described and/or illustrated herein can be implemented, individually and/or collectively, using a wide range of equipment and/or processing techniques.

Included in the discussion above are flowcharts showing steps and acts of processes that are used to produce MIM capacitors. It should be appreciated that the flowchart(s) included herein illustrate the functional information one of ordinary skill in the art can use to produce MIM capacitors using the techniques described herein. It should also be appreciated that, unless otherwise indicated herein, the particular sequence of steps and/or acts described in each flowchart is merely illustrative of the fabrication processes that can be implemented and can be varied in implementations and examples of the principles described herein.

It should be appreciated that some examples can be in the form of a method, of which at least one example has been provided. The acts performed as part of the method can be ordered in any suitable way. Accordingly, examples can be constructed in which acts are performed in an order different than illustrated, which can include performing some acts simultaneously, even though shown as sequential acts in illustrative examples.

Various aspects of the examples described above can be used alone, in combination, or in a variety of arrangements not specifically discussed in the examples described in the foregoing and is therefore not limited in its application to the details and arrangement of components set forth in the foregoing description or illustrated in the drawings. For example, aspects described in one example can be combined in any manner with aspects described in other examples.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

The word “exemplary” or “example” is used herein to mean serving as an example, instance, or illustration. Any embodiment, implementation, process, feature, etc. described herein as exemplary or as an “example” should therefore be understood to be an illustrative example and should not be understood to be a preferred or advantageous example unless otherwise indicated.

The phrase “and/or,” as used in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements can optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one example, to A only (optionally including elements other than B); in another example, to B only (optionally including elements other than A); in yet another example, to both A and B (optionally including other elements); etc.

Unless otherwise noted, the terms “connected to” and “coupled to” (and their derivatives), as used in the specification and claims, are to be construed as permitting both direct and indirect (i.e., via other elements or components) connection.

Unless otherwise noted, a first numeric value is “approximately” equal to a second numeric value if the first numeric value is within +20%, +10%, or +5% of the second numeric value.

Having thus described several aspects of at least one example, it is to be appreciated that various alterations, modifications, and improvements will readily occur to those skilled in the art. Such alterations, modifications, and improvements are intended to be part of this disclosure, and are intended to be within the spirit and scope of the principles described herein. Accordingly, the foregoing description and drawings are by way of example only.

What is claimed is:

1. An integrated circuit comprising:
one or more interconnects formed in a first metal layer;
one or more interconnects formed in a second metal layer above the first metal layer;
a capacitor disposed between the first and second metal layers, wherein the capacitor includes:
a first conductive plate disposed above the first metal layer;
a second conductive plate disposed above the first conductive plate; and
an insulating layer disposed between the first and second conductive plates;
one or more first vias connecting a first interconnect of the one or more interconnects of the second metal layer, the first conductive plate, and a first interconnect of the one or more interconnects of the first metal layer, the one or more first vias being configured to propagate a power supply signal or to couple to a power supply ground node; and
one or more second vias connecting the first interconnect of the one or more interconnects of the first metal layer to the first conductive plate, the one or more second via terminating below the second conductive plate.

2. The integrated circuit of claim 1, further comprising one or more third vias connecting a second interconnect of the one or more interconnects of the second metal layer, the second conductive plate, and a second interconnect of the one or more interconnects of the first metal layer, the one or more third vias being configured to propagate the power supply signal or to couple to the power supply ground node.

3. The integrated circuit of claim 2, further comprising one or more fourth vias connecting the second interconnect of the one or more interconnects of the second metal layer and the second conductive plate, the one or more fourth vias terminating above the first conductive plate.

4. The integrated circuit of claim 2, the one or more first vias being configured to propagate the power supply signal and the one or more third vias being configured to couple to the power supply ground node.

5. The integrated circuit of claim 2, wherein the insulating layer is a first insulating layer, and wherein the capacitor further includes:
a third conductive plate formed above the second conductive plate;
a second insulating layer disposed between the second and third conductive plates, and
the one or more first vias further connecting to the third conductive plate.

6. The integrated circuit of claim 5, further comprising one or more fifth vias connecting the first interconnect of the one or more interconnects of the second metal layer and the third conductive plate, the one or more fifth vias terminating above the second conductive plate.

7. The integrated circuit of claim 5, wherein the capacitor further includes:
a fourth conductive plate formed above the third conductive plate; and
a third insulating layer disposed between the third and fourth conductive plates, the one or more third vias further connecting to the fourth conductive plate.

8. The integrated circuit of claim 7, further comprising one or more sixth vias connecting the second interconnect of the one or more interconnects of the first metal layer to the second conductive plate and/or the fourth conductive plate, the one or more sixth vias terminating below the second metal layer; and
one or more seventh vias connecting the second interconnect of the one or more interconnects of the second metal layer and the fourth conductive plate, the one or more seventh vias terminating above the third conductive plate.

9. The integrated circuit of claim 7, wherein the capacitor further includes:
a fifth conductive plate formed above the fourth conductive plate;
a fourth insulating layer disposed between the fourth and fifth conductive plates, the one or more first vias further connecting to the third conductive plate and the fifth conductive plate;
one or more eighth vias connecting the first interconnect of the one or more interconnects of the second metal layer and the fifth conductive plate, the one or more eighth vias terminating above the fourth conductive plate;
wherein at least one of the eighth vias further connects to the third conductive plate and/or the first conductive plate; and
one or more ninth vias connecting the first interconnect of the one or more interconnects of the first metal layer to the third conductive plate and the first conductive plate, the one or more ninth vias terminating below the fourth conductive plate.

10. A method of forming a capacitor in an integrated circuit, the method comprising:
forming one or more interconnects in a first metal layer, a first conductive plate disposed above the first metal layer, an insulating layer disposed above the first conductive plate, a second conductive plate disposed above the insulating layer, and one or more interconnects in a second metal layer disposed above the second conductive plate;
forming one or more first vias extending at least from a first interconnect of the one or more interconnects of the first metal layer to a first interconnect of the one or more interconnects of the second metal layer, and connected at least to the first interconnect of the first metal layer, the first conductive plate, and the first interconnect of the second metal layer, the one or more first vias being configured to propagate a power supply signal or couple to a power supply ground node; and
forming one or more second vias connecting the first interconnect of the first metal layer to the first conductive plate, the one or more second vias terminating below the second conductive plate.

11. The method of claim 10, further comprising forming one or more third vias connecting a second interconnect of the one or more interconnects of the second metal layer, the second conductive plate, and a second interconnect of the one or more interconnects of the first metal layer, the one or more third vias being configured to propagate the power supply signal or to couple to the power supply ground node.

12. The method of claim 11, further comprising forming one or more fourth vias connecting the second interconnect of the one or more interconnects of the second metal layer and the second conductive plate, the one or more fourth vias terminating above the first conductive plate.

13. The method of claim 11, the one or more first vias being configured to propagate the power supply signal and the one or more third vias being configured to couple to the power supply ground node.

14. The method of claim 11, wherein the insulating layer is a first insulating layer, wherein the method further includes forming a second insulating layer above the second conductive plate and a third conductive plate above the second insulating layer and below the second metal layer, and wherein the one or more first vias further connect to the third conductive plate.

15. The method of claim 14, further comprising one or more fifth vias connecting the first interconnect of the one or more interconnects of the second metal layer and the third conductive plate, the one or more fifth vias terminating above the second conductive plate.

16. The method of claim 14, wherein the method further includes forming a third insulating layer above the third conductive plate and a fourth conductive plate above the third insulating layer and below the second metal layer, and wherein the one or more third vias further connect to the fourth conductive plate.

17. The method of claim 16, further comprising one or more sixth vias connecting the second interconnect of the one or more interconnects of the first metal layer to the second conductive plate and/or the fourth conductive plate, the one or more sixth vias terminating below the second metal layer.

18. The method of claim 16, further comprising one or more seventh vias connecting the second interconnect of the one or more interconnects of the second metal layer and the fourth conductive plate, the one or more seventh vias terminating above the third conductive plate.

19. A system comprising:
a power supply configured to provide a power supply signal; and
an integrated circuit including a load, a power supply line configured to provide the power supply signal to the load, one or more interconnects formed in a first metal layer, one or more interconnects formed in a second metal layer above the first metal layer, and a capacitor disposed between the first and second metal layers;
wherein the capacitor is coupled to the power supply line,
wherein the capacitor includes a first conductive plate disposed above the first metal layer, a second conductive plate disposed above the first conductive plate, and an insulating layer disposed between the first and second conductive plates, and
wherein the integrated circuit further includes:
one or more first vias connecting a first interconnect of the one or more interconnects of the second metal layer, the first conductive plate, and a first interconnect of the one or more interconnects of the first metal layer, the one or more first vias being configured to propagate the power supply signal, and
one or more second vias connecting the first interconnect of the one or more interconnects of the first metal layer to the first conductive plate, the one or more second via terminating below the second conductive plate.

20. The system of claim 19, wherein the load includes a processing core or an array of memory cells.
